(19) United States
(12) Patent Application Publication
(10) Pub. No.: US 2026/0016512 A1
(43) Pub. Date: Jan. 15, 2026

(54) HYBRID TIME-FREQUENCY REPRESENTATION (HTFR) BASED POWER CHARACTERIZATION

(71) Applicants: Alex STANKOVIC, Stanford, CA (US); Hanoch LEV-ARI, Newton, MA (US)

(72) Inventors: Alex STANKOVIC, Stanford, CA (US); Hanoch LEV-ARI, Newton, MA (US)

(21) Appl. No.: 19/261,898

(22) Filed: Jul. 7, 2025

Related U.S. Application Data
(60) Provisional application No. 63/669,193, filed on Jul. 9, 2024.

(51) Int. Cl. G01R 19/25; G01R 19/252; G01R 19/257; H03H 21/00

(52) U.S. Cl. CPC G01R 19/2509; G01R 19/2513; G01R 19/252; G01R 19/257; H03H 21/002

(57) ABSTRACT

In some embodiments, systems, methods, and apparatuses incorporating an hTFR-based power characterization system are provided. The system in various embodiments comprises a constant bandwidth (CB) module to generate a first group of time-frequency representation (TFR) values for a power signal acquired for a device using a first set of frequency sub-bands over a first frequency range, a constant Q (CQ) module to generate a second group of TFR values for the power signal using a second set of frequency sub-bands over a second frequency range, a TFR array generator coupled to both the CB and CQ modules to combine the first and second TFR values into an array of resultant TFR values, and a power characterization module to identify an anomaly with the device based on the array of resultant TFR values.

### CROSS-REFERENCE TO RELATED APPLICATION

This application claims the benefit of U.S. Provisional Application No. 63/669,193, entitled: HYBRID TIME-FREQUENCY REPRESENTATION (HTFR) BASED POWER CHARACTERIZATION, filed on Jul. 9, 2024, the entire contents of which are hereby incorporated by reference.

### TECHNICAL FIELD

Embodiments relate to the field of power transmission and distribution and, more specifically, to tools for characterizing power signals.

### BRIEF DESCRIPTION OF THE DRAWINGS

The disclosure may best be understood by referring to the following description and accompanying drawings that are used to illustrate embodiments of the invention. In the drawings:

FIG. 1 is a diagram showing a hybrid time and frequency representation (hTFR) system.

FIG. 2A shows a TFR diagram generated using an STFT of a current amplitude signal from a first power generation example.

FIG. 2B is a cross-sectional view of the TFR diagram of FIG. 2A taken at the fundamental frequency.

FIG. 3A shows a TFR diagram generated using a Continuous wavelet transform (CWT) of the current amplitude signal from the first example.

FIG. 3B shows a cross-section of the TFR diagram of FIG. 3A taken near the fundamental frequency.

FIG. 4A shows a cross-section of a power amplitude signal TFR generated using a CWT transform of a signal from a second power generation example.

FIG. 4B shows a cross-section of a TFR of the amplitude signal of FIG. 4A but uses an STFT transform to generate the TFR.

FIG. 5A shows a TFR diagram generated using an STFT transform with hamming filters of the power amplitude signal of the second example.

FIG. 5B is a cross-sectional diagram of the TFR diagram of FIG. 5A taken from a transient peak frequency.

FIG. 6A shows a TFR diagram generated using a Morse transform of the power amplitude signal of the second example.

FIG. 6B is a cross-sectional diagram of the TFR diagram of FIG. 6A taken from the transient peak frequency.

FIG. 7 is a diagram showing comparisons between DWT (left) and STFT (right) generated TFR cross-sections for the first example at the fundamental harmonic (top) and 5th harmonic (bottom).

FIG. 8 is a diagram showing a sub-band pattern of a 9-Hamming/14-Hamming hybrid-TFR scheme displaying the last and first two of the nine CB sub-bands (dash-dot line) and the first and last two of the fourteen CQ sub-bands (solid line).

FIG. 9 is a diagram showing two iso-Q curves for both the second example and another example using a synthetic-short-transient signal.

FIGS. 10A and 10B are diagrams showing contour plots of hybrid-TFRs for the second example generated using two distinct iso-Q sub-band patterns, both with Q=6.43 using a Hamming filter with ACQ=0.30, KCQ=26 (FIG. 10A) and A_{CQ}=1.36, K_{CQ}=12 (FIG. 10B).

FIG. 11 is a diagram showing a contour plot of a hybrid-TFR for the second example generated using a reduced-Q sub-band pattern.

FIG. 12 is a diagram showing a contour plot of a hybrid-TFR for the second example generated using an overly sparse sub-band pattern with Hamming filters.

FIG. 13 is a diagram showing a CQ-module cost curve along an iso-Q curve.

FIG. 14A is a diagram showing a hybrid-TFR using a 9-Hamming/14-Hamming sub-band pattern for the second example.

FIG. 14B is a diagram showing a cross-sectional view of the TFR diagram of FIG. 14A at the transient peak frequency.

FIG. 15A is a diagram showing a hybrid-TFR using a 9-Hamming/14-Morse sub-band pattern applied to the second example.

FIG. 15B is a diagram showing a cross-sectional view of the TFR diagram of FIG. 15A at a TFR cross-section at the transient peak frequency.

FIG. 16A is a diagram showing a reduced-Q hybrid-TFR using a 9-Hamming/14-Morse sub-band pattern for the second example.

FIG. 16B is a diagram showing a cross-section of the TFR diagram of FIG. 16A taken at a transient peak frequency.

FIG. 17 is a diagram showing a p-norm spectrogram representing the 3-phase current of the current signal of the second example using a 9-Hamming/14-Morse sub-band pattern.

FIGS. 18A and 18B are diagrams showing symmetrical sequence component spectrograms representing the three-phase currents of the second example using a 9-Hamming/14-Morse sub-band pattern for a positive sequence (FIG. 18A) and a negative sequence (FIG. 18B).

FIG. 19 is a diagram showing an Instantaneous power spectrogram for the synthetic short transient example using a 9-Hamming/14-Hamming sub-band pattern.

FIG. 20 shows voltage and current signals for the first example dataset with voltage signals (top) and current signals (bottom).

FIG. 21 shows voltage and current signals for a second example dataset with voltage signals (top) and current signals (bottom).

FIG. 22 shows voltage and current signals for a third example dataset with voltage signals (top) and current signals (bottom).

FIG. 23 shows a signal acquisition module (SAM) in accordance with some embodiments.

FIG. 24 is a block diagram generally showing a power distribution system.

FIG. 25 is a block diagram showing a system for generating an hTFR-based power characterization model(s) for use in an ML-based power generator/load apparatus characterization system in accordance with some embodiments.

FIG. 26 is a diagram illustrating a power characterization tool in accordance with some embodiments.

FIG. 27 is a block diagram of a server-based network computing system for implementing a power characterization system in accordance with some embodiments.

FIG. 28 shows a sub-band structure for a constant-Q pattern in accordance with some embodiments.

FIG. 29 is a flow diagram showing a method for identifying anomalies in a power system in accordance with some embodiments.

### DETAILED DESCRIPTION

The time-frequency representation (TFR) of power system waveforms poses a unique challenge because it involves several conflicting objectives. To begin with, accurate representation of dominant harmonics typically relies upon uniformly spaced sub-bands centered on the harmonics of interest with sufficient frequency resolution, and decent suppression of leakage from sidelobes. In addition, in-band transients should be captured. Capturing in-band transients (in the dominant harmonics) typically requires good time resolution. A signal analyzer employing a constant bandwidth (CB) transform can work well for these objectives. This type of analysis uses filters with a fixed universal bandwidth, meaning the bandwidth remains the same across all frequencies. For example, a filter might have a bandwidth of 3 Hz or 10 Hz, regardless of the center frequency. CB signal processing provides uniform resolution on a linear frequency scale. This means that the separation between harmonically related components is consistent, which is useful for detecting harmonic patterns. A Short-Time Fourier Transform (STFT) is an example of a good CB transform approach for achieving a reliable representation of both steady-state harmonic content and in-band transients.

In addition, with power systems analysis it is also desirable to be able to capture wide-band transients in a signal. Capturing wide-band transients typically requires a much higher time resolution. CB transforms typically do not work well for adequately capturing such wide-band transients. Constant-Q (CQ) transforms, on the other hand, can be used to achieve better time resolution at higher frequencies. CQ signal analysis uses filters where the bandwidth is a constant percentage of the center frequency. The quality factor (Q) is generally defined as the ratio of a filter's center frequency to its bandwidth, with this Q, for CQ analysis, generally remaining constant across the different frequency ranges being analyzed. With CQ transforms, fewer frequency bins are needed to effectively cover a given range, which is advantageous for signal components that can occur anywhere throughout a relatively wide frequency range.

Accordingly, in some embodiments, a hybrid time-frequency representation (hTFR) approach is provided that splits in at least two the frequency range of interest: a constant-bandwidth transform is used in a lower frequency range, while a constant-Q (CQ) transform is used in an upper frequency range. This can result in a more insightful depiction of wide-band transients, as well as harmonics of interest and their associated in-band transients.

The quality of the generated hTFR information will typically depend primarily on the combined CB/CQ sub-band patterns and, to a lesser degree, on the choice of filters used in the construction of the CB and CQ modules for the transforms.

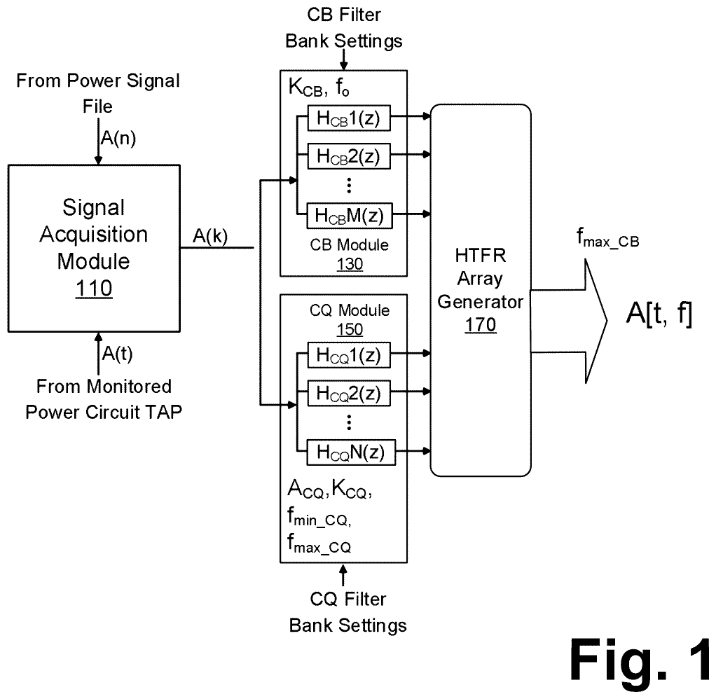

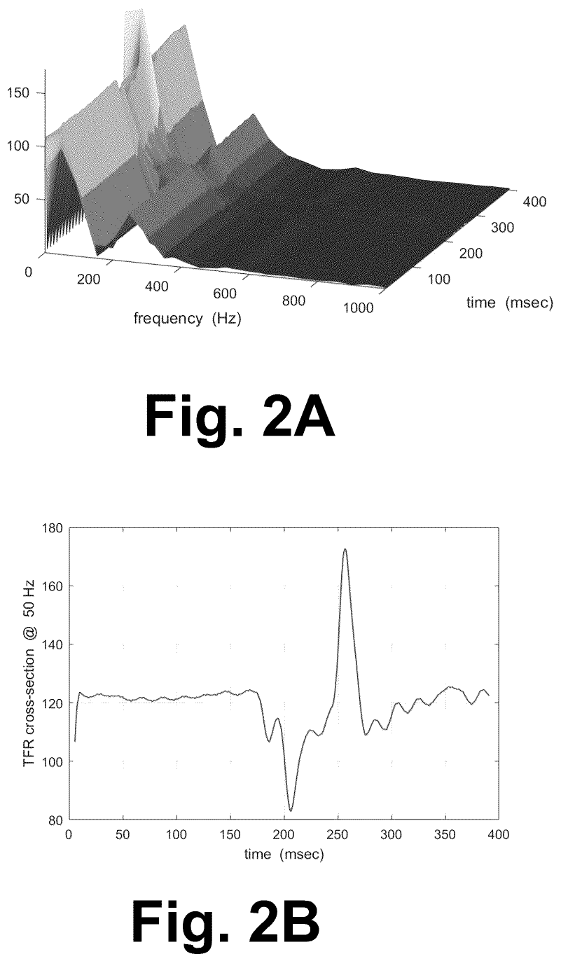

FIG. 1 is a diagram showing a hybrid time and frequency representation (hTFR) system. The system generally includes a signal acquisition module (SAM) 110, constant bandwidth (CB) module 130, constant Q (CQ) module 150, and hTFR array generation module 170, coupled as shown. The SAM 110 acquires digitized power signal samples from a power network or device TAP (test access point). It may monitor and digitize the samples itself, or it may serve as an interface to one or more already existing sampled power signal data sets. The data may correspond to one or more different power signals, e.g., current, voltage, or power signals, and will typically represent signal magnitudes at specific discrete time values. A signal may be represented, as in the figure, as A[k], i.e., an amplitude at a point in discrete time k.

This signal (A[k]), referred to generally as a power signal, is fed into both the CB and CQ modules. The CB module has a bank of filters, HCB1(z) through HCBM(z), to perform time-to-frequency transform operations on the input power signal at different frequency sub-bands on a lower frequency range within a range of interest. The module has at least two parameters, the number of filters, KCB, and the fundamental sampled power signal frequency. Any suitable filter construct, such as low-pass or band-pass finite impulse response (FIR) filter construct, may be used with an appropriate time-to-frequency transform operation implementing constant bandwidth processing. This is discussed in greater detail below.

The CQ module 150 also has a bank of filters, HCQ1(z) through HCQN(z), but these filters are used for performing time-frequency transformation on the input signal at separate constant Q sub-bands within an upper frequency range of the frequency range of interest. As with the CB filters, any suitable filter constructs, such as FIR filters, may be used. The CQ module has parameters including KCQ, the number of CQ filters, ACQ, the relative amplitude of over-lapping CQ sub-bands, f_{min_CQ}, the lower frequency of the CQ frequency range, and fmax_CQ, the upper frequency of the CQ frequency range.

The quality of the generated hTFR information will depend primarily on the combined CB/CQ sub-band pattern and, to a lesser degree, on the choice of prototype filters used in the construction of the two modules of the transform.

The signal generation module 170 accumulates and combines the outputs from the CB and CQ filters to create an array A[t, f] data for the hTFR. It may simply record values coming out of the filters and insert them into their proper time slots, or it may perform further processing, such as interpolation, linear or non-linear, to synthesize better resolution in the representation.

### CB and CQ Modules

The following sections discuss approaches for constructing CB and CQ modules in accordance with some embodiments.

As already pointed out, time-frequency analysis of power system waveforms poses a special challenge because it involves several different objectives. Accurate representation of dominant harmonics typically utilizes uniformly spaced sub-bands centered on the harmonics of interest, with sufficient frequency resolution and decent suppression of leakage from sidelobes. But, at the same time, capturing in-band transients (in the dominant harmonics) typically relies upon good time resolution. In some embodiments, a sensible compromise between these two requirements for the CB TFR portion may be to utilize, for example, sub-bands whose width is f₀, which results in time-resolution Δt≈T≡1/f₀. At the same time, capturing wide-band transients typically relies on a higher time resolution. Using CQ sub-bands can achieve this objective by facilitating wider sub-bands in the higher frequency range, say, above 11f₀ or so.

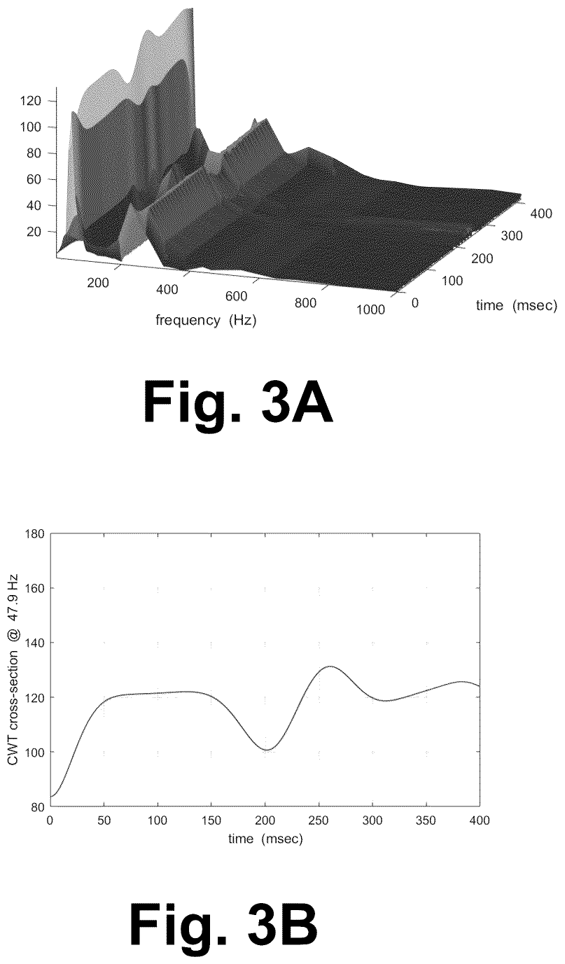

While the continuous wavelet transform (CWT), a CQ implementation, provides a largely similar representation in the higher frequency range (FIG. 3A), its depiction of time-variation in the fundamental harmonic exhibits excessive smoothing (FIG. 3B). (FIGS. 3A/3B are diagrams showing continuous wavelet transform (CWT) based TFR generations of a current signal in Example 1 (f₀=50 Hz), using 4 sub-bands-per-octave: full TFR (3A) and a TFR cross-section near the fundamental frequency (3B).)

This excessive smoothing is caused by the narrow width of the sub-band that contains the fundamental harmonic. The width of this sub-band in this example is approximately 10 Hz, which results in poor time resolution (≈100 msec). Since low sub-band density, e.g., less than 4 sub-bands per octave, is generally impractical to implement, time resolution at the fundamental frequency may not be significantly improved.

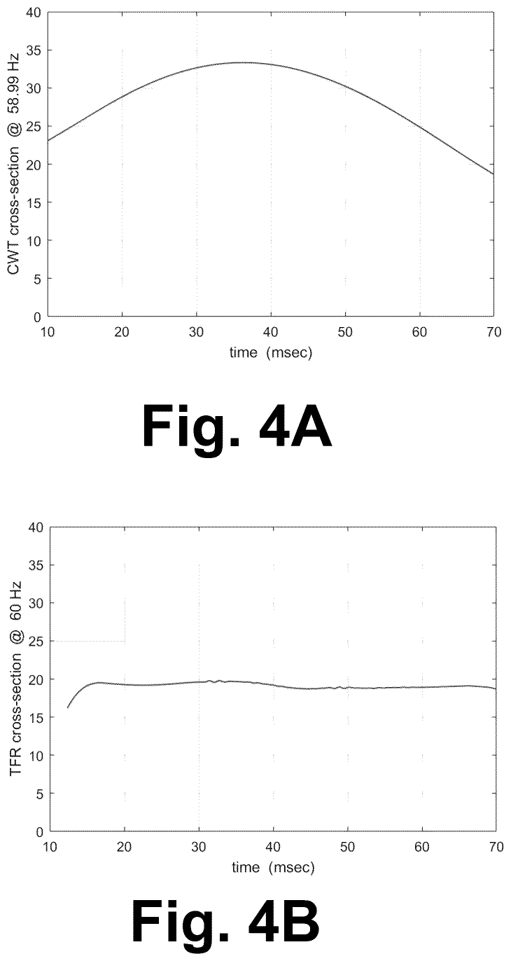

A similar result is suggested by other examples, such as example 2 below (a data set for a wind-farm generation system, as illustrated in FIGS. 4A and 4B. In summary, a constant-bandwidth (CB) transform, such as the STFT, is a desirable method for reliable representation of both steady-state harmonic content and in-band transients for lower frequency ranges in power signal analysis.

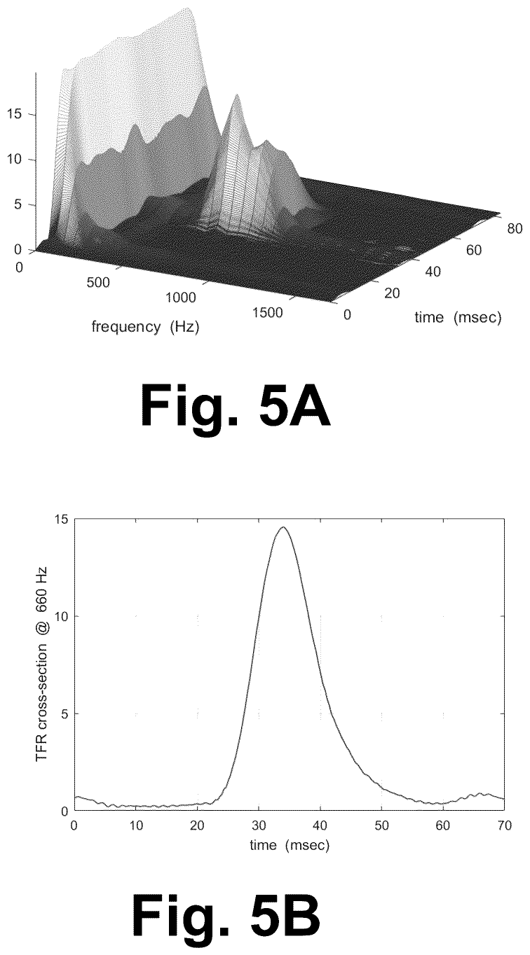

However, the situation is reversed in the presence of a high-frequency wideband transient. It turns out that a constant-Q (CQ) transform, like the CWT, provides a more insightful depiction of such transients, due to its improved time resolution at higher frequencies. The second example (Example 2) illustrates this capability. FIGS. 5A and 5B are diagrams showing STFT-generated TFRs for a current in Example 2 (Hamming window, f₀=60 Hz) full TFR graph (5A) and a cross-section at the transient peak frequency (5B).

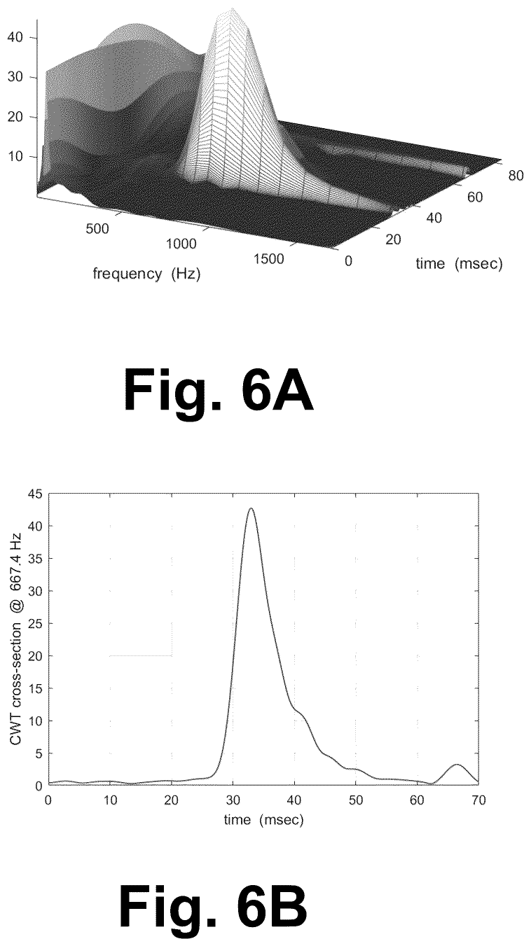

Both FIGS. 5A/5B (STFT) and FIGS. 6A/6B (CWT) display a transient peak concentrated in the time interval 23-50 msec and the frequency range 500-1000 Hz (which was generated as a result of a bank of capacitors being switched on in the wind farm generator system). (FIGS. 6A/6B are CWT-generated TFR representations for the current signal in Example 2 (Morse wavelet, 6 sub-bands-per-octave, f₀=60 Hz), full TFR (6A) and a TFR cross-section at the transient peak frequency (6B).)

However, the TFR cross-section through this peak is somewhat wider in the STFT-generated TFR (FIG. 5A) than in its CQ counterpart (FIG. 6B). It can thus be seen that CQ transforms can perform better for representing wide-band high-frequency transients.

Accordingly, a hybrid-TFR (hTFR) approach may be employed. The hTFR splits the frequency range of interest into at least two sub-ranges where a constant-bandwidth transform (e.g., the STFT) may be used in the lower frequency range, while a constant-Q transform (e.g., generalized-STFT or CWT) may be used in the upper range. The terms CB module and CQ module will be used to describe these two distinct components of the hybrid-TFR. Guidelines for the application-specific design of each module are provided in the following sections. (Note that for simplicity and case of understanding, the following discussion will employ two sub-ranges for generating an hTFR of a signal over a range of interest. However, in some embodiments, more sub-ranges with different transform types and sub-band patterns may be used depending upon particular design considerations.)

Note that while any suitable transform approach may be used for either CB or CQ module design, for CQ modules, it has been observed that the generalized-STFT and the CWT transforms allow for flexible control of frequency-resolution, time-resolution, inter-sub-band leakage, and flexible output rate control of the resulting TFR. In particular, when an important goal is detailed time-frequency analysis or accurate localization of signal transients, the quality of features extracted from power system waveforms via either CWT or a generalized-STFT may be preferable to those provided by a DWT or DOST transform. The main difference between CWT/generalized-STFT techniques and the other transform approaches—which directly impacts the resulting TFR quality—is the underlying design philosophy of each transform. For instance, the primary design objectives of a DWT scheme typically include constructions of an orthonormal basis for the space of finite energy waveforms. Feasible DWT prototype sub-band filter choices may be constrained by the objectives of satisfying a dyadic dilation equation and providing a controllable degree of smoothness, neither of which correlate well with good frequency resolution and/or suppression of sidelobe leakage. Consequently, resulting sub-band patterns generally have a low, non-adjustable sub-band density (e.g., a single sub-band per octave), which compromises frequency resolution and also makes it hard to match dominant harmonics with DWT sub-bands. In addition, Dates usually rely on critical down-sampling of their sub-bands, which degrade their time resolution. In contrast, CWT/generalized-STFT schemes can provide adjustable and higher sub-band densities. Typical values may be in the range of 4-10 sub-bands-per-octave. Furthermore, STFT filters (windows) such as Hamming, Blackman, or Chebyshev can typically perform well with regard to leakage suppression, and the same may be true for Morse filter designs that can be used with CWT implementations.

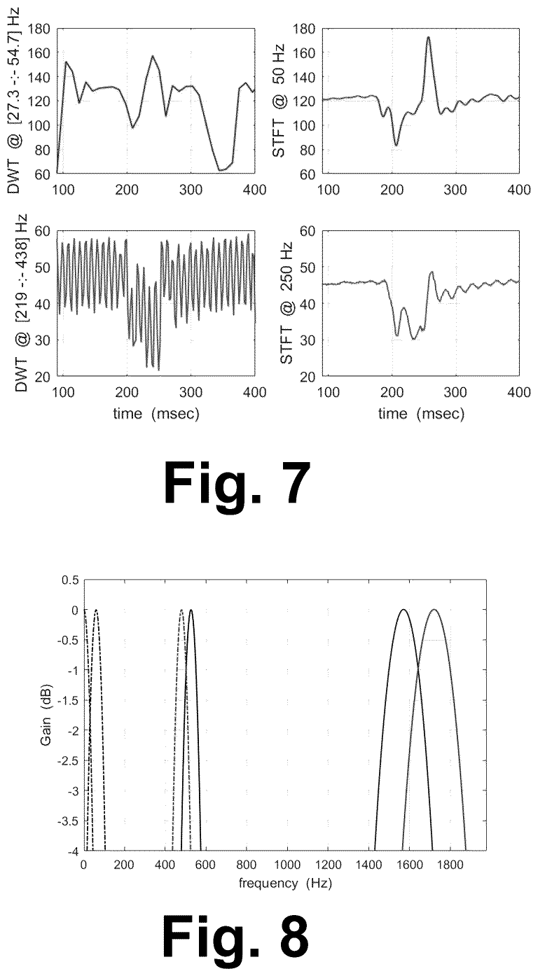

In addition, it has been observed that DWT methods can be less appealing than hybrid techniques that use, e.g., STFT and CWT approaches. FIG. 7 provides an illustration of some DWT-based time-frequency features for Example 1 (f₀=50 Hz). The DWT sub-band that contains this fundamental frequency is 27.3 Hz≤f≤54.7 Hz (FIG. 7, top-left). It is observed that the STFT counterpart, shown in the top-right panel of FIG. 7, provides a significantly more accurate depiction of the onset of an in-band transient, which starts at t≈180 msec, as well as the steady-state regime within the interval that precedes this transient. Similarly, the 5th harmonic, which falls within the relatively wide DWT sub-band 219 Hz≤f≤438 Hz (FIG. 7, bottom-left), is much easier to discern in the appropriate STFT sub-band, centered at f=5f₀=250 Hz. Similar observations apply to scenarios that exhibit wide-band transients in addition to dominant harmonics, such as in the wind farm example.

It can thus be concluded that a spectrogram generated by a well-designed generalized-STFT or CWT may be preferable, in most power system applications, to feature extraction via the DWT for identifying wide-band transients. Consequently, the remainder of this disclosure is limited to hybrid-TFR schemes whose CQ modules employ adequate sub-band density (e.g., at least 4 sub-bands-per-octave), analytic/near-analytic filters, and non-decimated sub-band processing.

### Design of the CB-Module

Since an objective of the CB module is an accurate depiction of dominant harmonics, both in a steady state and in the presence of slowly varying transients, harmonic-centered sub-bands for the CB module may be employed.

In some embodiments, a single-cycle-long window as the prototype low-pass filter may be used. Moreover, in some embodiments, a reasonable choice for the number of CB-sub-bands may be 7≤K_{CB}≤11.

The sub-band filters for this module may be given by,

$$\begin{matrix}{h}_{k} ( t ) = h ( t ) {e}^{jk 2 π {f}_{0} t} \\ 0 \leq k \leq {K}_{CB}\end{matrix}$$

where h(t) is a single-cycle-long window, i.e., Tₕ=1/f₀. The 3 dB bandwidth of each sub-band filter hₓ(t) is

$${Δ}_{f , k}^{( PD * 3 )} = {C}_{f}^{( PD * 3 )} {f}_{0}$$

where the coefficient

$${C}_{f}^{( PD * 3 )}$$

relates the 3 dB bandwidth of a given window function h(t) to the window duration.

### CB/CQ-Junction Constraints

The CB/CQ-junction is the point of transition between the frequency ranges of the CB-module and the CQ-module, i.e., the intersection points between the magnitude responses of the highest sub-band in the CB-module and the lowest sub-band in the CQ-module. The frequency of this transition point can be controlled by adjusting the parameter f_{min_CQ}, which defines the lower edge of the nominal frequency range covered by the CQ module.

A convenient way to describe this degree of freedom is in terms of the junction edge ratio (JER),

$$JER = \frac{lowest CQ subband - edge frequency}{highest CB subband - edge frequency}$$

Note that the sub-band filters of a CQ-module may be designed to intersect at a prescribed level A_{CQ}. This means that one has several options for choosing a JER-value (and, thus, an f_{min_CQ}-value), namely,
Set JER=1, which results in a level of intersection at the CB/CQ junction that is different from either A_{CB} or A_{CQ}.
Set JER=1 and design the CQ-module to have the same intersection level as the CB-module, i.e., set A_{CQ} to be equal to A_{CB}. This approach results in uniform sub-band overlap for the entire CB+CQ filter bank.
Determine JER so that the junction intersection level matches A_{CB}: this results in JER<1 when A_{CQ}>A_{CB}, but JER>1 when A_{CQ}<A_{CB}.
Determine JER so that the junction intersection level matches A_{CQ}: this results in JER>1 when A_{CQ}>A_{CB}, but JER<1 when A_{CQ}<A_{CB}.

Once a JER value has been determined, the corresponding f_{min_CQ}-value,

$${f}_{min \_ CQ} = JER ( {K}_{CB} + 1 / 2 ) {f}_{0}$$

provides a needed input for the CQ-module design step, which is described in the following subsection. It should be pointed out that even the last two of these four design options generate JER≈1, so that all four design options generate very similar sub-band patterns.

### Design of the CO-Module

The design of any constant-Q filter bank typically starts with the construction of its sub-band pattern. The input variables for this step are: (a) the frequency range [f_{min_CQ} f_{max_CQ}] covered by the filter bank, (b) K_{CQ}, the desired number of sub-bands, and (c) A_{CQ}—the desired level of intersection between magnitude responses of adjacent sub-bands. While the value of f_{min_CQ} depends primarily on K_{CB} (the number of sub-bands in the CB-module), the top frequency f_{max_CQ} can be selected based on prior knowledge about the nature of transients contained in the waveform of interest. When such information is not readily available, one can resort to the default choice f_{max_CQ}=Fₛ/2. The number of sub-bands in the CQ module serves as a design variable that should be chosen subject to an application-specific upper bound K_{CQ}≤K_{CQ,max}. The upper bound K_{CQ,max} depends on A_{CQ}, as well as the frequency variables f₀, f_{min_CQ} and f_{max_CQ}, as specified in [0096] and [0097] below.

Construction of a sub-band pattern for the CQ module starts with the key relation

$$Γ = {( \frac{{f}_{m ax}}{{f}_{m i n}} )}^{1 / {K}_{CQ}}$$

Next, the scaling factor Γ is used to determine: (a) sub-band density, which is equal to sub-bands-per-logarithmic frequency band (e.g., octave), and (b) Sub-band center frequencies:

$${f}_{c , {K}_{C Q} - r} = \frac{Γ + 1}{2 {Γ}^{r + 1}} {f}_{m ax}$$

$$0 \leq r \leq {K}_{C Q} - 1$$

Information about sub-band frequency ranges can be used to formulate a junction bandwidth constraint, which is described below.

The CQ module is designed to provide a gradually increasing sub-band width, which controls the time/frequency-resolution trade-off in each sub-band. Thus, it is reasonable to require that the nominal width of the lowest CQ-sub-band—i.e., (Γ−1) fₘᵢₙ—is at least as large as the bandwidth of the filter used in the highest CB-sub-band, as illustrated in FIG. 8. (FIG. 8. Sub-band pattern of a 9-Hamming/14-Hamming hybrid-TFR scheme, subject to both CB/CQ-junction constraints (with A_{CQ}=1 dB), displaying: (a) last and first two of the nine CB sub-bands (dash-dot line), and (b) first and last two of the fourteen CQ sub-bands (solid line). Frequency parameters: f₀=60 Hz and fₘₐₓ=1800 Hz, resulting in fₘᵢₙ=502.6 Hz.)

Since the former is equal to the A_{CQ}-bandwidth of the corresponding sub-band filter, we will use the same prescribed drop level to define filter bandwidth for the highest CB-sub-band, viz.,

$${Δ}_{f , C B}^{( P D * {A}_{C Q} )} = {C}_{f , C B}^{( P D * {A}_{C Q} )} {f}_{0}$$

FIG. 8 demonstrates the consequences of enforcing both CB/CQ-junction constraints, namely, K_{CQ}≤K_{CQ,max} and the JER. For example, setting K_{CB}=8, fₘₐₓ=1800 Hz, and A_{CQ}=1 dB in this example (Example 2, windfarm with f₀=60 Hz) results in fₘᵢₙ=502.6 Hz and K_{CQ,max}=14. The corresponding sub-band pattern, generated with K_{CQ}=14, has monotone non-decreasing sub-band widths, and a 1 dB sub-band intersection level at the CB/CQ-junction. (Note that the shorthand label “9-Hamming/14-Hamming” indicates the number of sub-bands and the filter prototype used in the CB-module/CQ-module, respectively.)

Notice that the bandwidth of the first CQ-sub-band is very nearly the same as the bandwidth of the last CB-sub-band: this is a by-product of setting K_{CQ} equal to its upper bound. Moreover, this property holds regardless of the A_{CQ}-value used to determine K_{CQ,max} via [0096] and [0097], which also means that the resulting distinct sub-band patterns of the CQ-module—one pattern for each (A_{CQ}, K_{CQ,max})-pair, where A_{CQ} can assume any value—all share the same Q-factor. This observation forms the basis for an effective CQ-module design method.

### Design of Sub-Band Filters

Sub-band filters for the CQ module can be designed from a low-pass prototype. It may be observed that:

$${h}_{K - r} ( t ) = \frac{1}{{Γ}^{r} {σ}_{K}} g ( \frac{c}{{Γ}^{r} {σ}_{K}} ) {e}^{j 2 π {f}_{c , K - r} t}$$

$$0 \leq r \leq K - 1$$

where we set K=K_{CQ} and the sub-band center frequencies f_{c,K-r} are as given in [0084]. The bandwidth-scaling coefficient σ_{K} is given by the expression

$${σ}_{K} = \frac{{Δ}_{f}^{( P D * A )}}{{f}_{ma x} ( 1 - \frac{1}{Γ} )}$$

### Iso-Q Curves

The final step in designing the sub-band pattern of a CQ-module amounts to choosing the parameter A_{CQ}, which controls the upper bound K_{CQ,max}, as well as selecting the number of

$$CQ - sub - bands {K}_{C Q} \leq {K}_{C Q , m ax} , where$$

$${K}_{C Q , m ax} = floor ( \frac{{log}_{2} ( \frac{{f}_{m ax}}{{f}_{m i n}} )}{{log}_{2} ( 1 + {C}_{f , CB}^{( PD * {A}_{CQ} )} \frac{{f}_{0}}{{f}_{m i n}} )} )$$

In other words, once the CB-module design step has been completed, and fmax_CQ has been selected, we are left with the task of choosing a point in the (A_{CQ},K_{CQ})-plane.

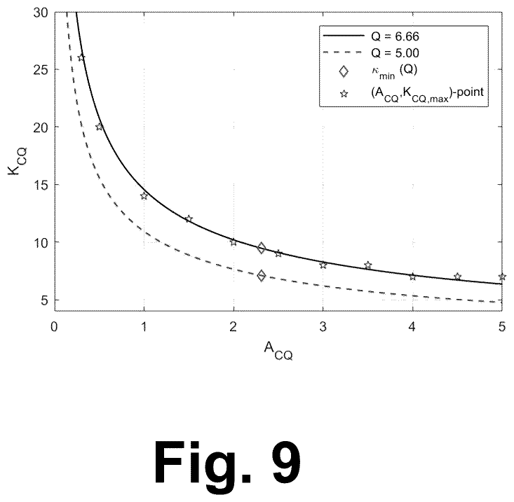

Each such choice determines a CQ-module sub-band pattern. In particular, choosing an (A_{CQ}, K_{CQ})-pair determines the Q-factor of the resulting CQ module and, thus, controls frequency resolution (a continuous-frequency property) in each sub-band of this module. It turns out that distinct (A_{CQ}, K_{CQ})-pairs can give rise to the same Q-factor. The set of all such pairs is a hyperbola-like curve (FIG. 9), which we call an iso-Q curve. On the other hand, the location of an (A_{CQ}, K_{CQ})-point on a given iso-Q curve controls the density of our discretized-frequency grid, and thus impacts the level of detail displayed by Xₖ(⋅)—the discrete-frequency TFR. In summary, a CQ-module sub-band pattern may be determined by: (a) choosing an iso-Q curve of interest, and (b) selecting an (A_{CQ}, K_{CQ})-point on this curve. We shall use this viewpoint throughout this section as a foundation for orderly CQ-module design.

An explicit expression for (A_{CQ}, K_{CQ})-points on an iso-Q curve of interest can be obtained by expressing the scaling factor Γ in terms of the Q-factor and the bandwidth parameter ρ_{f}, namely,

$$Γ ( {A}_{CQ} ; Q ) = \frac{2 Q + {ρ}_{f} ( {A}_{CQ} )}{2 Q - {ρ}_{f} ( {A}_{CQ} )}$$

$$The expression$$

$${K}_{C Q} = round ( \frac{{log}_{2} ( \frac{{f}_{max \_ CQ}}{{f}_{min \_ CQ} ( {A}_{C Q} )} )}{{log}_{2} ( \frac{2 Q + {ρ}_{f} ( {A}_{CQ} )}{2 Q - {ρ}_{f} ( {A}_{CQ} )} )} )$$

is a functional representation of the iso-Q curve, with fₘᵢₙ (A_{CQ}) determined via the JER expressions [0071] and [0078]. FIG. 9 shows two such iso-Q curves, for two distinct values of the Q-factor: Q=6.66 and Q=5.00. Notice that the upper bound on K_{CQ}, indicated in this figure by several star-shaped markers located at selected (A_{CQ}, K_{CQ,max})-points, practically coincides with the iso-Q curve for Q=6.66.

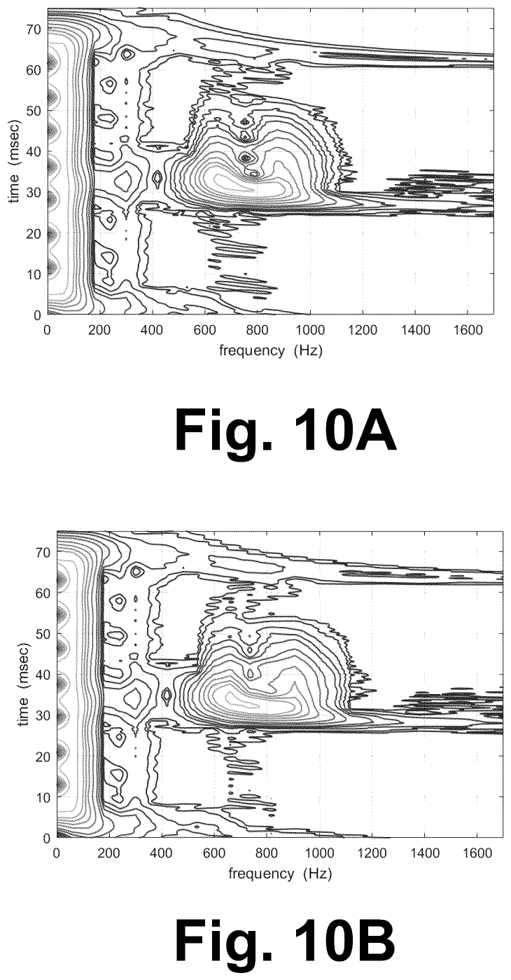

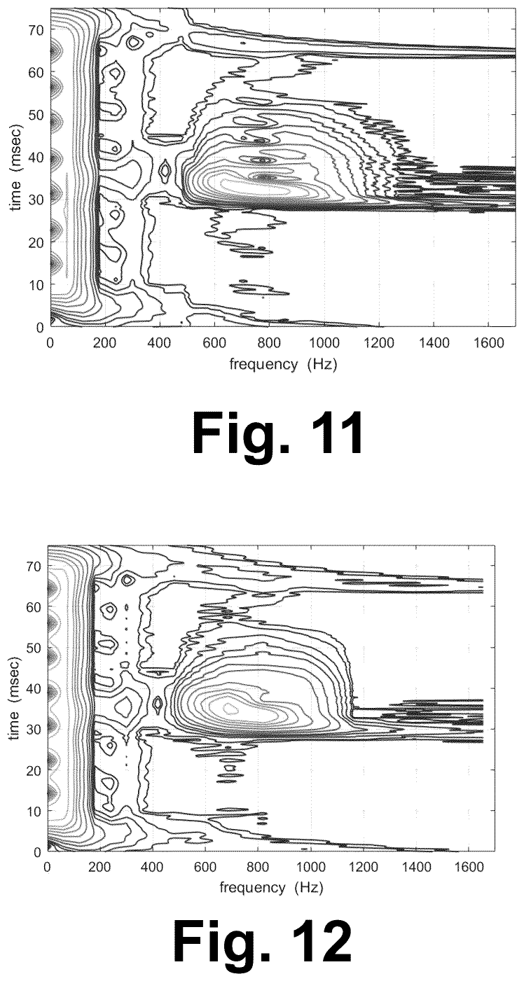

As pointed out above, the Q-factor of a CQ-module controls sub-band filter bandwidth and thus determines the trade-off between time- and frequency resolution for each sub-band. Consequently, iso-Q sub-band patterns generate very similar TFRs, which differ in small details, due to a different level of overlap between sub-bands. FIGS. 10A and 10B illustrates this property: although the two designs differ in their (A_{CQ}, K_{CQ})-pair values, the corresponding TFRs are almost identical. (FIGS. 10A and 10B are diagrams showing contour plots of hybrid-TFR (Example 2) generated by two distinct iso-Q sub-band patterns, both with Q=6.43, using a Hamming prototype, (A_{CQ}, K_{CQ})=0.30, 26 (FIG. 10A) and (A_{CQ}, K_{CQ})=1.36,12 (FIG. 10B) with frequency parameters f₀=60 Hz and f_{max_CQx}=1800 Hz.)

CQ-modules that correspond to (A_{CQ}, K_{CQ})-points located on an iso-Q curve with a lower Q-value, such as Q=5 in FIG. 9, should be considered when the time resolution of high-frequency sub-bands is of prime concern. However, an excessive reduction of the Q-factor may result in severe distortion of the resulting time-frequency representation. This effect is due to degraded frequency resolution, as well as increased leakage from adjacent sub-bands, both of which tend to “smear out” frequency detail.

Once a desired Q-value has been selected, which determines a particular iso-Q curve and, thus, a particular trade-off between time- and frequency-resolution, the next step in the CQ-module design process is selection of a particular (A_{CQ}, K_{CQ})-point on this curve. We observe that points in the upper-left segment of an iso-Q curve result in more CQ-sub-bands, thus increasing operation cost. On the other hand, choosing a (A_{CQ}, K_{CQ})-point in the lower-right segment of such a curve reduces the number of sub-bands-which determines the density of our discretized frequency grid-thus causing loss of fine detail, such as the shape of the “ravine” seen in FIGS. 10A and 10B, located at f_{c}≈750 Hz within the time interval 40 msec≤t≤50 msec. Thus, in order to prevent excessive loss of detail, one should consider imposing a lower bound on the number of sub-bands.

One way of generating such a bound is by exploiting the lower bound on sub-band density: it induces a Q-dependent approximate lower bound for the number of sub-bands, i.e.,

$${K}_{CQ} \geq {κ}_{m i n} ( Q ) , where$$

$${κ}_{m i n} ( Q ) = ceil ( \frac{{log}_{2} ( \frac{{f}_{m ax}}{{f}_{m i n} ( {A}_{C Q} )} )}{{log}_{2} ( {Γ}_{c r} ( Q ) )} ) and$$

$${Γ}_{c r} ( Q ) = \frac{4 Q + {ρ}_{f}^{( P D * 10 )}}{4 Q - {ρ}_{f}^{( P D * 10 )}}$$

In other words, each iso-Q curve has its own lower bound on K_{CQ}, as indicated by the “diamond” markers in FIG. 9. Violating this lower bound—i.e., choosing K_{CQ}<Kₘᵢₙ (Q)—results in loss of fine detail, as can be seen in FIG. 12: in particular, the “ravine” seen in FIGS. 10A and 10B (located at f_{c}≈750 Hz) is completely absent from the contour plot in FIG. 12, which uses K_{CQ}=7 even though Kₘᵢₙ (Q)=9.1. We conclude that acceptable choices of an (A_{CQ}, K_{CQ})-point should be restricted to the upper-left segment of the iso-Q curve, namely, left of the Kₘᵢₙ (Q) marker. (FIG. 12 is a diagram showing a contour plot of a hybrid-TFR for Example 2 generated by an overly sparse sub-band pattern with Q=6.54 using a Hamming prototype, (A_{CQ}, K_{CQ})=4,7 and with frequency parameters of f₀=60 Hz and f_{max_CQ}=1800 Hz, resulting in Kₘᵢₙ (Q)=9.1.)

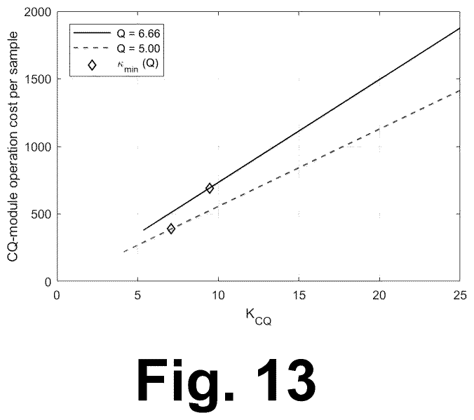

The other criterion that should be taken into account when making a specific (A_{CQ}, K_{CQ}) choice is cost (per input sample) of operating the CQ-module, which increases linearly with K_{CQ} (or very nearly so) along each iso-Q curve (FIG. 13). This property follows from the observation that T_{h,K}—the length of the finite length window h_{K}(t), associated with the K-th sub-band—is given by the expression

$${T}_{h , K} = \frac{{C}_{f , CQ}^{( P D * {A}_{CQ} )}}{{f}_{max \_ CQ} ( 1 - 1 / Γ )}$$

where we rely on the relation between the nominal width of a sub-band and the A dB bandwidth of the corresponding sub-band filter, as illustrated in FIG. 29. Next, notice that the cost of operating the k-th sub-band filter equals the discrete-time length of this FIR filter, which is

$$ceil ( \frac{{T}_{h k}}{{T}_{s}} ) = ceil ( {F}_{s} \frac{{c}_{f , CQ}^{( P D * {A}_{CQ} )}}{{f}_{ma x} ( 1 - 1 / Γ )} {Γ}^{{K}_{C Q} - k} )$$

$$1 \leq k \leq {K}_{C Q}$$

The total cost (per input sample) of operating the CQ module is obtained by adding up the operating costs of the individual sub-band filters, viz.

Operation cost (per sample) of a

$$CQ - module = {C}_{f , CQ}^{( P D * {A}_{C Q} )} ( \frac{{F}_{s}}{{f}_{m i n}} - \frac{{F}_{s}}{{f}_{m ax}} ) \frac{Γ}{{( Γ - 1 )}^{2}}$$

where we used the fact that Γ^{K}^{_{CQ}}=fₘₐₓ/fₘᵢₙ and, for simplicity, ignored the rounding operation ceil(⋅). Plotting this cost as a function of K_{CQ}—for points along an iso-Q curve-reveals a nearly linear behavior (see FIG. 13).

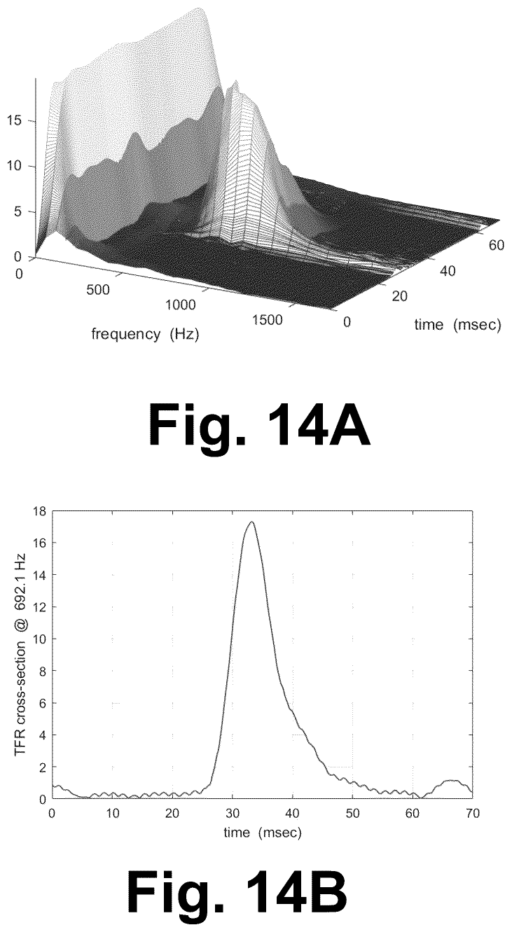

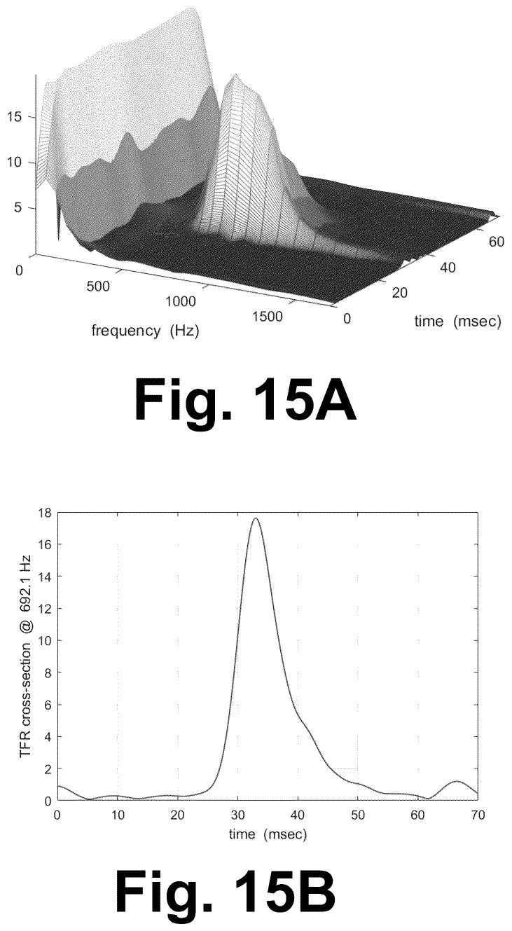

Examination of FIGS. 9 and 13 suggests that a reasonable choice for the number of sub-bands in this example is an integer value where 10≤K_{CQ}≤15 which, equivalently, corresponds to the parameter choice 1≤A_{CQ}≤2. This range of K_{CQ} values somewhat exceeds the lower bound [0109] and [0111], at the expense of a modest increase in operation cost. In addition, we observe that the operation cost of the CQ-module is directly proportional to the waveform sampling rate Fₛ, which should discourage excessive over-sampling. For instance, a satisfactory representation of the windfarm transient is obtained with fₘₐₓ=1800 Hz (see FIGS. 14, 15 below), which implies that a sampling rate of 3600 samples/sec would have been sufficient to generate this TFR. (FIGS. 14A and 14B are diagrams showing a hybrid-TFR, using a 9-Hamming/14-Hamming sub-band pattern (with A_{CQ}=1 dB), applied to Example 2 showing a full TFR plot (14A) and a TFR cross-section at the transient peak frequency (14B) with frequency parameters of f₀=60 Hz and fₘₐₓ=1800 Hz, resulting in Q=6.40 and κₘᵢₙ (Q)=9.2.

FIGS. 15A and 15B are diagrams showing a hybrid-TFR scheme using a 9-Hamming/14-Morse sub-band pattern with A_{CQ}=1 dB, γ=3, β=27, for Example 2 showing full TFR plot (124A) and a TFR cross-section at the transient peak frequency (15B) with frequency parameters: f₀=60 Hz and fₘₐₓ=1800 Hz, resulting in Q=6.48 and κₘᵢₙ (Q)=8.9.

### The Combined CB/CQ Transform

Putting together the two modules generates a TFR that covers the entire frequency range of interest, from DC to f_{max_CQ}. In the wind-farm example one version of this hybrid-TFR consists of nine constant-width sub-bands (because KCB=8) and fourteen constant-Q sub-bands (with A_{CQ}=1 dB and K_{CQ}=K_{CQ,max}=14), all generated from a Hamming-window prototype (FIGS. 14A, 14B). The nine harmonics contained in the CB portion of this TFR are, of course, equivalent with the ones obtained from a standard Hamming-based STFT: compare the TFR in the lower frequency range 0≤f≤f_{min_CQ} of FIGS. 14A, 14B with the same range in FIGS. 5A, 5B. In particular, notice how well this TFR scheme portrays the fundamental harmonic, both in steady-state and in the presence of an in-band transient.

Similar results are obtained when a Morse prototype—with γ=3, β=27, and A_{CQ}=1 dB—is used to implement the CQ module (FIGS. 15A, 15B). Both the TFR and its cross-section are practically identical to those shown in FIGS. 14A, 14B, which confirms our observation that choice of a CQ prototype has a minor impact on TFR quality, once the CQ-sub-band pattern has been finalized. In fact, the only noticeable difference between the Morse-based and Hamming-based TFRs in this example is the presence of a small ripple in the TFR cross-section plot of FIGS. 14A, 14B, which is caused by the sidelobes of the Hamming window. Finally, a comparison with FIGS. 5A and 5B (uniform STFT) underscores the advantages of using a constant-Q sub-band pattern for the portrayal of wide-band transients: our two hybrid TFR schemes (i.e., FIGS. 14A, 14B and 15A, 15B) display a taller transient peak while also achieving a better time-resolution in the TFR cross-section for this peak.

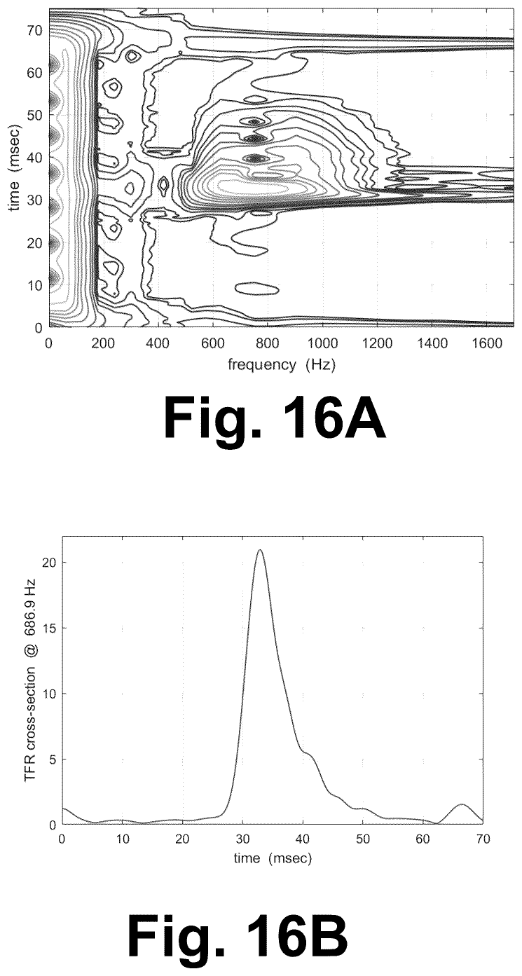

Reducing the Q-factor in this (windfarm) example from Q=6.4 to Q=5.0 by changing from A_{CQ}=1 dB to A_{CQ}=0.6 dB results in a barely noticeable improvement in time resolution. Compare FIG. 16B with FIG. 15B. On the other hand, this “reduced-Q” scheme suffers from a significantly degraded frequency resolution. Compare the contour plot in FIG. 16B with the ones in FIGS. 10A, 10B. These observations suggest that a “reduced-Q” approach should be used with caution: the improvement in time resolution that a reduction of the Q-factor can achieve may be, in some cases, outweighed by a degradation in frequency-resolution. (Note that FIGS. 16A and 16B are diagrams showing a reduced-Q hybrid-TFR using a 9-Hamming/14-Morse sub-band pattern with A_{CQ}=0.6 dB, γ=3, β=27, applied to Example 2 with a contour plot (16A) and a TFR cross-section at the transient peak frequency (16B) with frequency parameters of f₀=60 Hz and fₘₐₓ=1800 Hz resulting in Q=5.00 and Kₘᵢₙ (Q)=6.9.)

In general, a combined CB/CQ transform may be determined by the following seven design parameters: (1) the fundamental frequency, f0, (2) the number of CB-sub-bands, which is K_{CB}+1, (3) the frequency f_{max_CQ} to be analyzed, which is also the top CQ frequency, f_{max_CQ}, (4) the level of intersection, A_{CQ}, between adjacent CQ-sub-bands, (5) the number of CQ-sub-bands, which is K_{CQ}, (6) the window, or filter, type chosen for the CB module, and (7) the window, or filter, type chosen for the CQ module. This means a CB/CQ transform may be characterized by this 7-clement set. The CB window will usually be a low-pass filter, but the CQ-window prototype can be either low-pass or band-pass, as discussed above. Notice that the design of the CB module should be completed before one can determine f_{min_CQ}, which serves as input to the CQ-module design phase.

### Hybrid-TFR for Polyphase Waveforms

It should be pointed out that time-frequency analysis in power system applications involves polyphase current and voltage waveforms, where each single-phase waveform gives rise to a distinct TFR. One can also view this representation as a pair of polyphase TFRs, one for current, and the other one for voltage.

In a three-phase system, each polyphase TFR includes a set of three complex waveforms (one for each phase) associated with every sub-band,

$${X}_{k} ( t ) = [ \begin{matrix}{X}_{k}^{( a )} ( t ) & {X}_{k}^{( b )} ( t ) & {X}_{k}^{( c )} ( t )\end{matrix} ]$$

A scalar spectrogram that combines information from all three phase components can be generated from such a polyphase TFR by using a vector norm of interest.

For instance, using the p-norm:

$${‖ {X}_{k} ( t ) ‖}_{p} = {[ {\vert {X}_{k}^{( a )} ( t ) \vert}^{p} + {\vert {X}_{k}^{( b )} ( t ) \vert}^{p} + {\vert {X}_{k}^{( c )} ( t ) \vert}^{p} ]}^{1 / p}$$

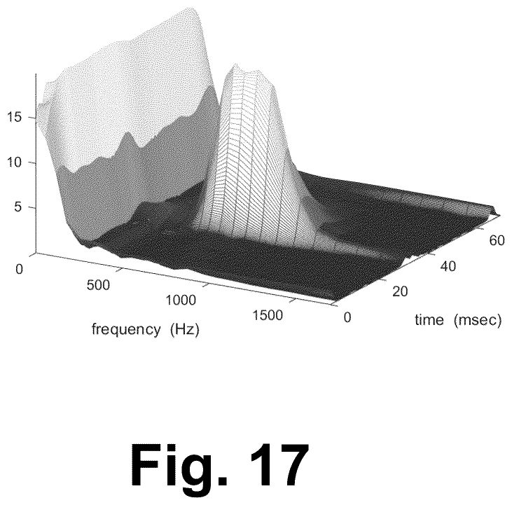

results in a scalar spectrogram, such as the one shown in FIG. 17. Notice how this approach preserves information about both the lower harmonic content and the higher-frequency wide-band transient: compare this spectrogram with the one shown in FIG. 15.

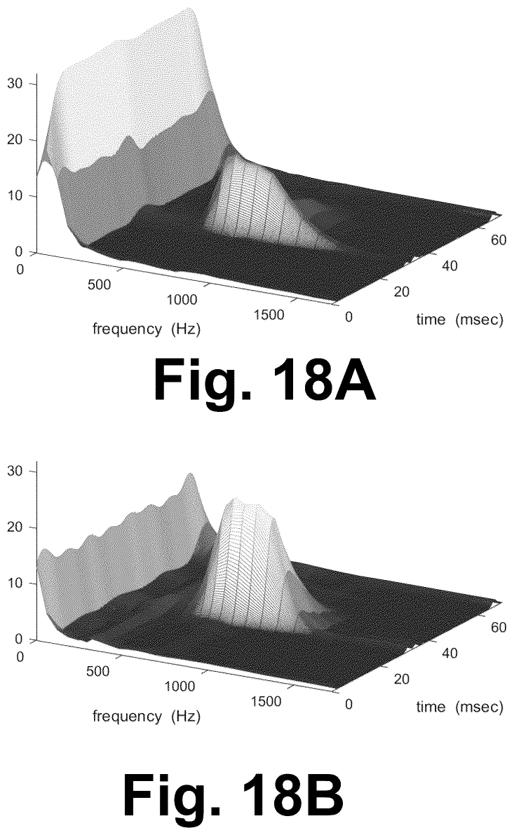

Alternatively, one could also evaluate a separate spectrogram for each one of the symmetrical sequence components of Xₖ(t). The resulting spectrograms for the positive and negative sequence components of a 3-phase current are shown in FIG. 18A and 18B. Notice that the positive sequence component (top spectrogram) captures well the lower harmonic content but shows a highly attenuated transient peak. At the same time, the reverse is true for the negative sequence component. Similar information can also be obtained for a three-phase waveform from the (α,β)-components generated by the Clarke transform. (FIGS. 18A and 18B are diagrams showing symmetrical sequence component spectrograms representing the 3-phase currents of example 2 using a 9-Hamming/14-Morse sub-band pattern with A_{CQ}=1 dB, γ=3, ß=27 showing the positive sequence (18A) and the negative sequence (18B) with frequency parameters of f₀=60 Hz and fₘₐₓ=1800 Hz resulting in Q=6.48 and κₘᵢₙ(Q)=8.9.)

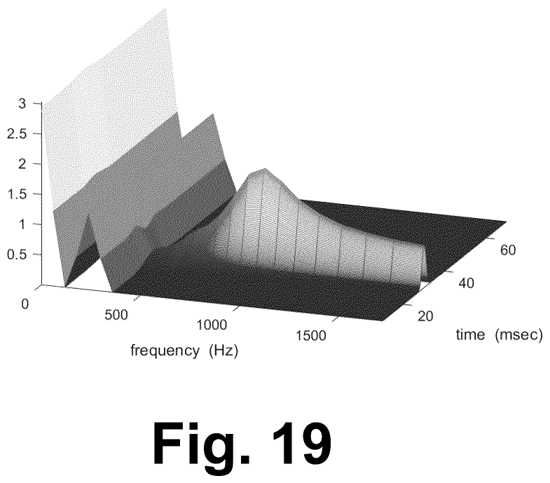

FIG. 19 is a diagram showing an instantaneous power spectrogram (Example 3) using a 9-Hamming/14-Hamming sub-band pattern (with A_{CQ}=1 dB with frequency parameters of f₀=60 Hz and fₘₐₓ=1800 Hz resulting in Q=6.48. It can be seen that combining voltage and current information from the corresponding polyphase TFRs, as well as using such joint information to generate features of interest for monitoring and event detection applications, may be employed in a variety of ways. For example, a different approach to address the “polyphase TFR challenge” is to construct a TFR of a scalar waveform that combines, in some physically meaningful way, polyphase current and voltage information, such as the instantaneous power p(t)=v(t)i>(t). The resulting spectrogram, evaluated for our synthetic short transient example, exhibits characteristics similar to the one generated from a current waveform. We can thus see that while p(t)-based spectrograms may be helpful in capturing wideband transients, they require careful interpretation when used to determine the harmonic content of voltage and current waveforms.

### EXAMPLE SCENARIOS

### Example 1 Paper Mill Load

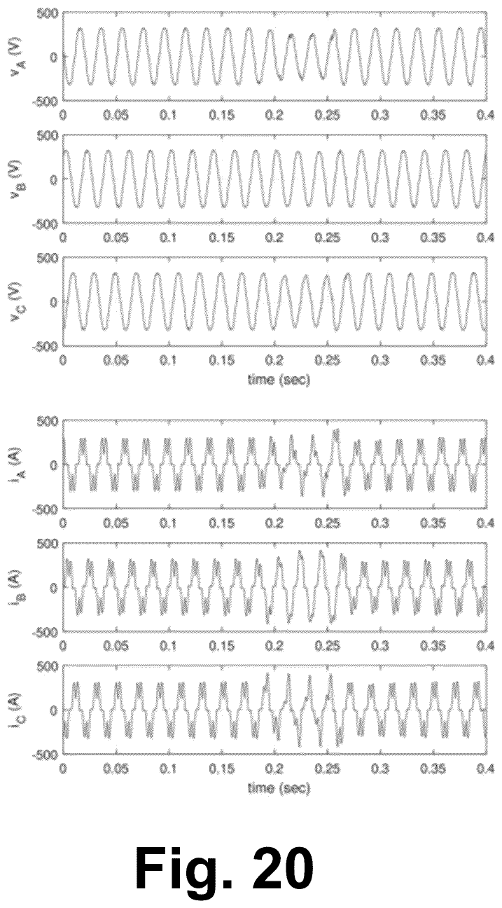

In a first example, power signals (current and voltage) were acquired for a paper mill electrical service load. The signals are illustrated in FIG. 20. A hybrid TFR analysis was performed on the signals and indicated a transient within the otherwise expected harmonics profile for power supplied to the mill. This paper mill included enough electrical equipment to facilitate a production capacity of 0.175,000 tons of paper per year. The total power consumed by this plant is 35 MW, and the fundamental frequency is 50 Hz. The dataset was recorded at 140 samples/cycle (=7000 samples/seconds).

### Example 2 Wind Farm Generation System

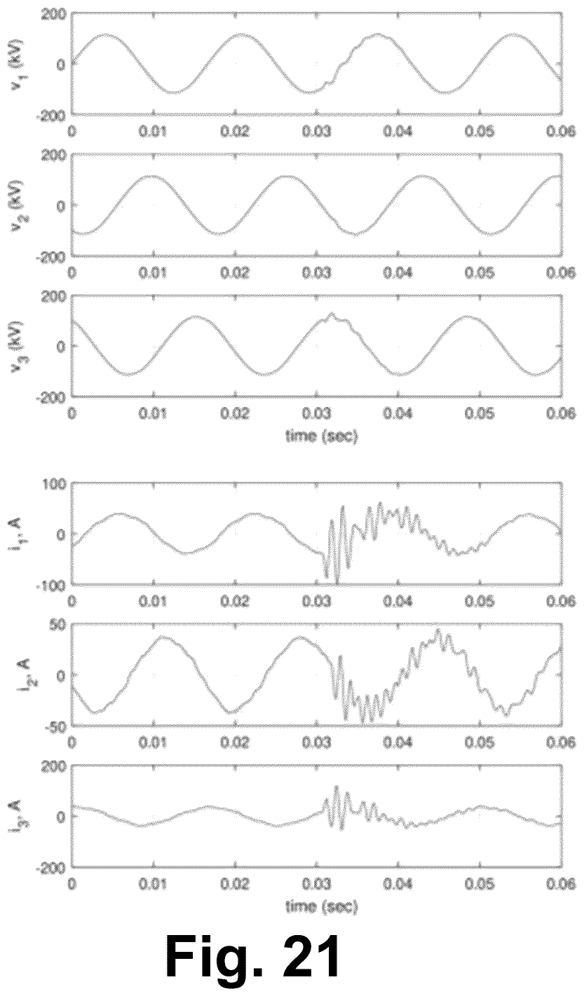

In a second example, power signals (current and voltage) were acquired for a wind farm power generation system. The signals are illustrated in FIG. 21.

A hybrid TFR analysis was performed on the signals and indicated a short transient in one of the current phase waveforms, which was caused by switching in a bank of shunt capacitors. This dataset was recorded at 128 samples/cycle (=7680 samples/sec.).

### Example 3 Synthesized Scenario

A three-phase system, driven by balanced fundamental and fifth harmonic voltages, and an injected 15-th harmonic transient, limited to the interval from. t=0.03 seconds to t=0.035 seconds, viz.,

$${v}_{transient} ( t ) = 5.5 {e}^{- t / 0.0018} cos ( 15 {ω}_{0} ( t - 0.03 ) )$$

$${i}_{transient} ( t ) = 0.9 {e}^{- t / 0.0018} cos ( 15 {ω}_{0} ( t - 0.03 ) - 1.4 )$$

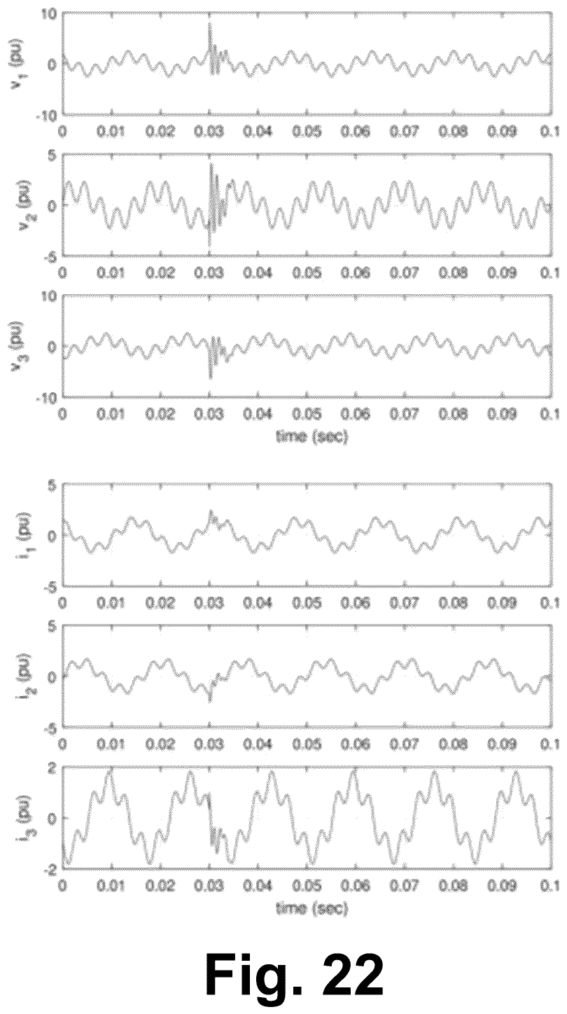

Voltage and current waveforms are shown in FIG. 22. The unbalanced load consists of resistive-inductive impedances Z₁=Z₂=Z₃=(1+j 0.4 k)Ω, where k denotes the harmonic index. The fundamental frequency is f₀=60 Hz, so that ω₀=120π rad/second. Plots were generated using 256 samples/cycle (=15,360 samples/second).

### Power Analysis Systems

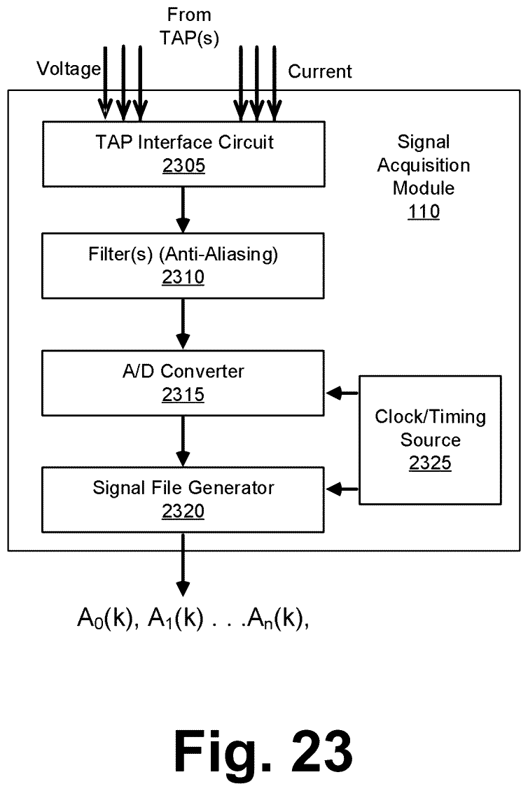

FIG. 23 shows a signal acquisition module (SAM) in accordance with some embodiments. The SAM generally includes a TAP (test access point) interface circuit 2305, one or more filters 2310, analog to digital converter (ADC) 2315, signal file generator 2320, and a clock/timing control source 2325, all coupled together as shown.

The TAP interface circuit may include any suitable components to acquire signal information, whether from a high-voltage test point or a low-power test port. High voltage signals in power distribution systems are typically monitored using specialized equipment and techniques designed to handle the extreme voltages involved. Depending on the network load or generator environment and analysis objectives, different approaches may be employed. For example, for high voltage nodes to be monitored, a voltage (or potential) transformer may be used to step down a high voltage to a lower, safer level that can be measured by instrumentation. These transformers can provide a scaled-down replica of the high-voltage signal for monitoring purposes. Other approaches may use capacitive voltage dividers, high voltage probes, optical sensors, or other interface solutions.

Once the signal to be analyzed is in a manageable form, it then may be conditioned, e.g., through one or more filters 2310 such as for anti-aliasing. It is then digitized, e.g., through the ADC 2315, which feeds the signal file generator 2320 to generate a digitized and time-stamped version of the sampled test signal, to compile the digital signal with the timing information into the power signal. The clock/timing source 2325 synchronizes the digited signal samples and allows them to be appropriately time-stamped through the signal file generator. The clock/timing source may be as simple as a clock in a computing system such as a controller or processing system, or it may include timing inputs from external sources such as through GPS, for example, to coordinate timing if more than one TAP is being monitored to generate the power signal file. Note that the SAM may be formed, for example, by using and putting together off-the-shelf parts, or it may be implemented with existing signal capture apparatuses such as with phasor measurement units (PMUs) or other signal acquisition products.

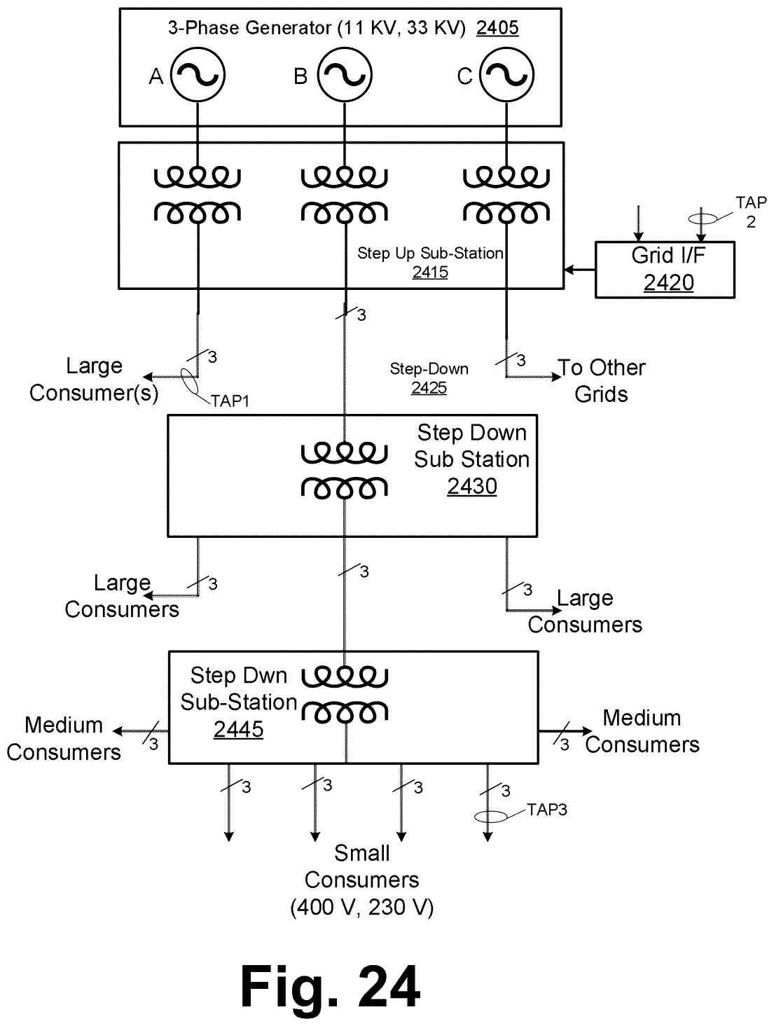

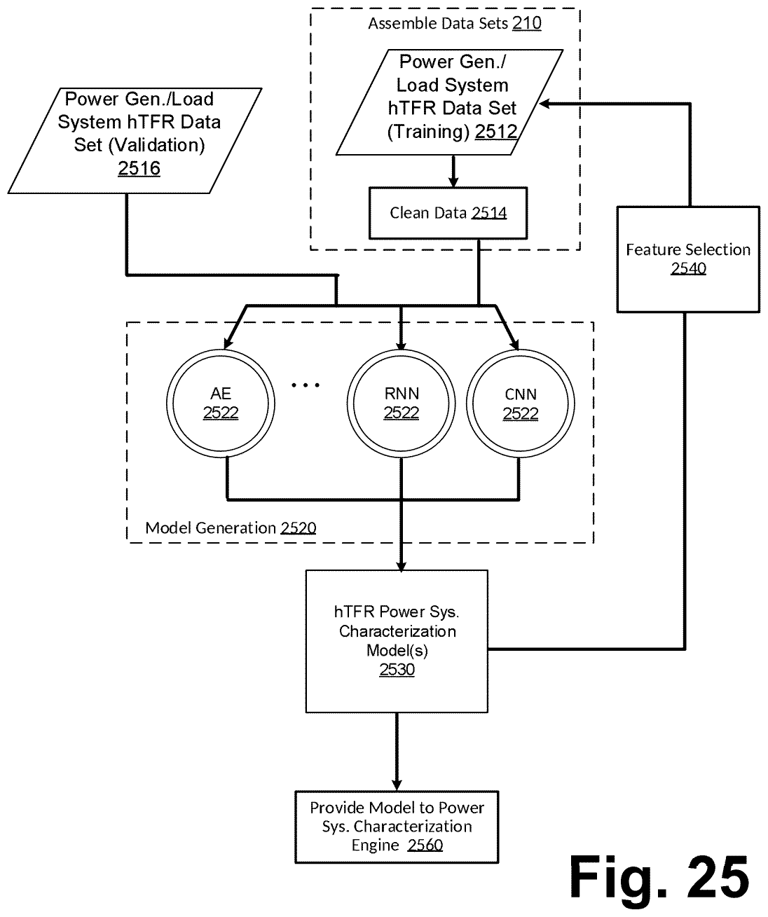

FIG. 24 is a block diagram generally showing a power distribution system. The diagram illustrates examples of points in the overall system where power signals may be monitored for hTFR analysis at various test access points (TAPs). The system includes a 3-phase primary power generation station 2405, a high voltage step-up substation 2415, an intermediate step-down substation 2430, and primary/secondary distribution step-down substations 2445. From the generation station at 2405, the power is stepped up to a very high level (e.g., up to 400 KV) at step-up substation 2415. From here, a high-voltage transmission system transfers the power to the intermediate step-down station at 2430. It also may transfer some of the power to other grids and/or receive power from other grids, e.g., through a grid interface 2420. The step-down station at 2430 steps down the power to a more manageable level, e.g., 15 KV. This power may be supplied to very large consumers, such as large factories or other systems. The power also may be provided to the primary and secondary step-down stations at 2445, where it is stepped down even further, e.g., 1 KV to medium consumers and 400 or 230 V to smaller consumers. Thus, it can be seen that a TAP may be disposed in a variety of different places within a power network, anywhere from the power generation station itself down to small consumer loads such as at a factory or building. In addition, a power network may be as large as a distribution system in the figure, or it may be as small as a network in a building, a vehicle or a small generation source. Any entity, commercial, industrial, and residential, may use an hTFR power characterization system to characterize a power delivery or load network in any variety of environments. For example, vehicles such as ships, aircraft, road vehicles, and trains may be characterized. Characterization systems may also be used by utilities for operations monitoring, equipment monitoring, and service to customers, and other entities such as managers of large facilities (commercial and industrial), equipment manufacturers, insurance/homeowners for building monitoring, operators of microgrids and distributed energy resources (sources or storage), and other entities may also use PC systems as discussed herein.

At a TAP, a signal access module (SAM) may sample and collect data from one or more signals, such as current, power, and/or voltage signals at any or all of three different phases, over a given test period (e.g., 5 minutes, 20 minutes, etc.). The monitored signal(s) may be sampled at a suitable sampling frequency, typically greater than 1 kHz and commonly near or even above 15.36 kHz for 60 Hz signals (256 samples per period) or even up to and above hundreds of kHz, for example, in distribution PMUs. Higher sampling rates can provide better information but can also consume much memory, depending on the interval of time over which a signal is sampled, and data is accumulated. In some embodiments, a running data acquisition window may be used and monitored, for example, in a power characterization system to identify anomalies or events, e.g., based on ML inference comparisons. In other schemes, specific sample sets may be collected, such as when a load is to come on or off a line.

There are a variety of applications for using hTFR PC (power characterization) systems. For example, with equipment monitoring, signatures of transients (e.g., turn-on) can be used to detect deterioration and the remaining useful life of a component. They may also be used as inputs to protection devices, especially for the system-level protection that often needs a fine-grain event classification. They also can be used at inputs to control devices to adequately identify an operating condition before a proper control setting is selected. In another example, they may be used for monitoring or certification of building electrical installation for safety and insurance purposes.

FIG. 25 is a block diagram showing a system for generating an hTFR-based power characterization model(s) for use in an ML-based power generator/load apparatus characterization system in accordance with some embodiments. The power generator/load apparatus characterization system (or simply power characterization system, PCS) may be used to aid in the characterization and/or forensic analyses of dynamic PQ events in a generator and/or load apparatus under scrutiny. The model generation system generally includes a data assembly block 2510, a model generation block 2520, one or more power system characterization models 2530, a feature selection block 2540, and an interface 2560 to make the model(s) available to a power characterization engine.

The data assembly block 2510 corresponds to generating and assembling labeled sets of IC package feature set instances (2512) and cleaning/conditioning the data at 2514 to make it amenable for ML model training at 2520. For example, the use of hTFR outputs 2512 may be employed to obtain more useful ML features by transforming monitored voltage and/or current traces (e.g., six I-V signals in a 3-phase circuit) into 11 separate power component features, or by simply generating time and frequency data from a hTFR module 2514 off of a single, or combination of several different, signal(s) such as p=vₐiₐ+v_{b}i_{b}+v_{c}i_{c}, q=( [symbol] vₐ)iₐ+( [symbol] v_{b})i_{b}+( [symbol] v_{c})i_{c}, where ( [symbol] vₓ) denotes the Hilbert-transformed signal vₓ or others. An adaptive hTFR can be designed by optimizing the parameters of the CB module 130 and/or the CQ module 150 to enhance the performance of the characterization blocks 2530 and 2560. Similarly, several engines 2560 can be run in parallel to improve the characterization of heterogeneous events. Regardless, the data set may be fed into a supervised training scheme and then later applied to a semi-supervised training scheme as the ML models extract additional features from the data. Alternatively, in some embodiments, unsupervised clustering techniques may be initially used to identify key features and feature relationships, while supervised ML schemes may be used to train ML models and then use them for power generator/load system characterizations. Depending on the approach(es), one or several different ML algorithms may be employed.

ML algorithm selection determines how the model will find patterns in the collected data. The algorithm stands behind the ML model. The same model can use various algorithms. Simultaneously with the choice of algorithm, the collected data may undergo a series of transformations to shape the training set. For example, the data may be edited, refined, labeled, and enhanced manually to achieve acceptable data quality for future models.

With the depicted implementation, the hTFR-generated PCS data set instances are provided to one or more different ML model training engines 2522. The generated model(s) are files containing the layers and weights that are trained to identify multiple correlations or patterns in the datasets. The models are trained from datasets using one or more of the machine learning algorithms, which are used to analyze and remember that learning data. As in the depicted embodiment, they may be used to generate, in parallel, a power characterization system (PCS) model for the ML methods in some embodiments, ML techniques such as convolutional neural networks (CNN), recurrent neural networks (RNN) such as a Long-Short-Term Memory (LSTM) scheme, autoencoder (AE) structures, and other schemes may be employed. Other methods including but not limited to Bayesian Regression, Random Forest, Perceptron, Decision Tree, KNearest Neighbor, Model N, Model N-1, Neural Network, and Expert Systems, among others, could also be used for the ML model builders 2522.

A majority of the labeled package data sets 2512 may be used for training, i.e., building the models, while the remaining labeled data sets 2516 may be used to test the models to assess their accuracy against actual package instance costs used as controls.

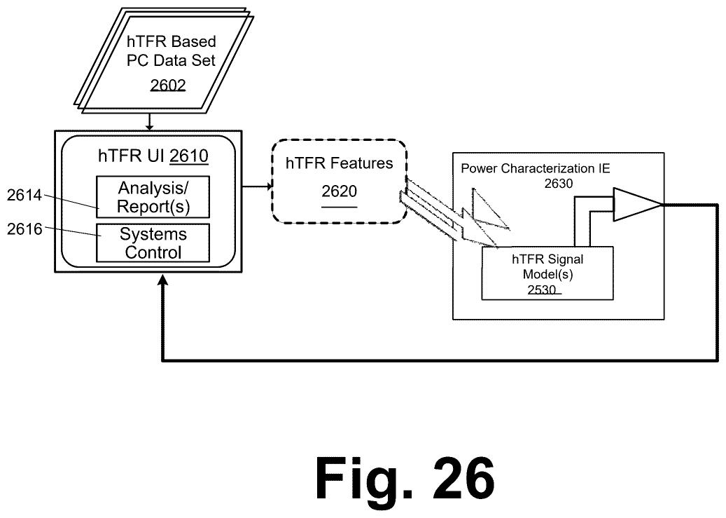

At 2530, one or more models may be selected. As shown in the diagram, features may be selected (or prioritized) at 2540. The feature definitions and forms may be refined, e.g., based on a list of features that have higher predictive power, and used to refine existing and additional labeled training, and validation, training sets for tuning of the power system characterization model. From here, the model may be used in a power system characterization engine as will be discussed below with reference to FIG. 26.

FIG. 26 is a diagram illustrating a power characterization tool in accordance with some embodiments. The tool includes a user interface engine 2610 and a power characterization inference engine 2630 to characterize a properly conditioned power network data set 2620. The inference engine 2630 uses one or more generated model(s) 2530 and provides the results back to the user through the user interface 2610.

The user interface 2610 allows a user to enter and/or manage hTFR-based power characterization data set instances for characterization. The interface 2610 has a module 2614 to allow a user to manage the input data set(s) and to provide a user with reports, or other data forms, to analyze the results of the power characterization. It also may have a module 2616 to allow a user to manage control of the power network that is being characterized.

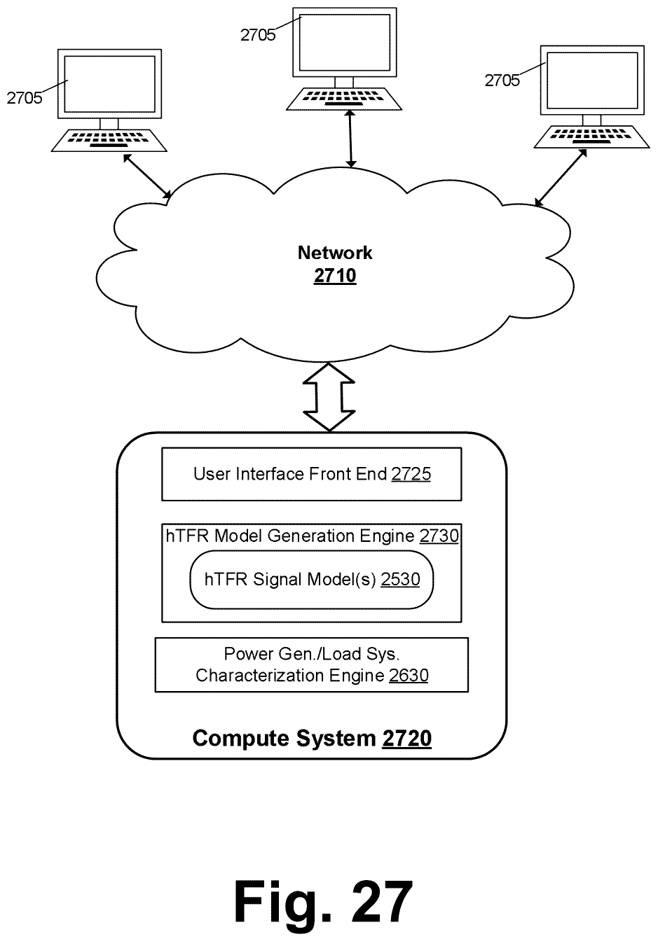

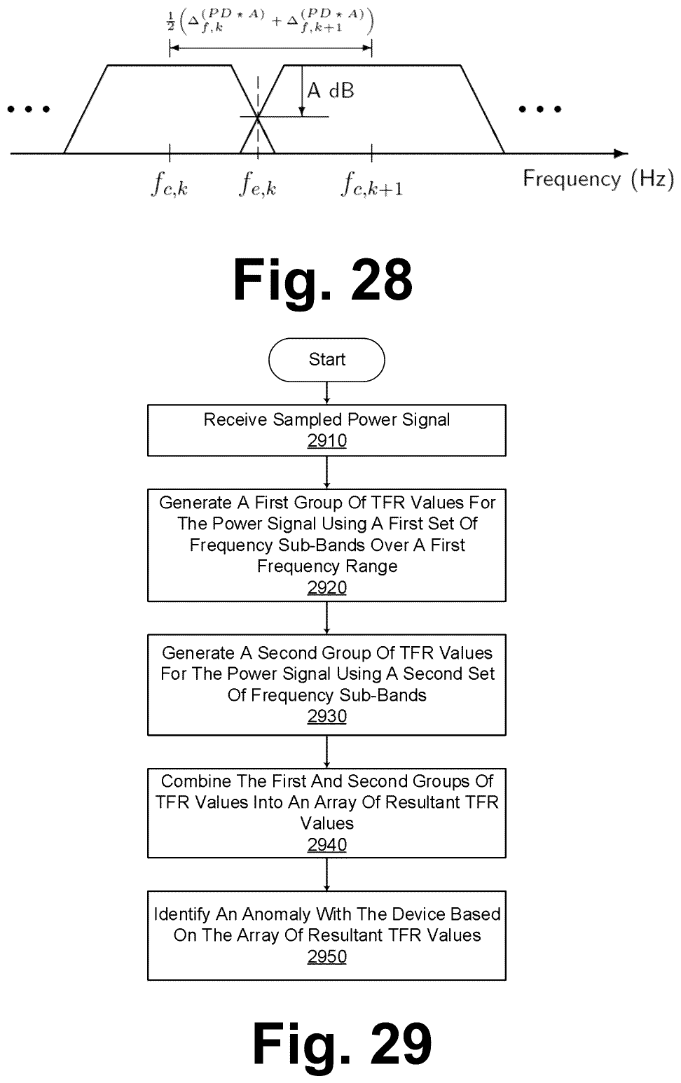

FIG. 27 is a block diagram of a server-based network computing system for implementing a power characterization system in accordance with some embodiments. The system includes a plurality of terminal devices (PCs, servers, mobile workstations, etc.) 2705 coupled to a server computing system 2720 through compute network 2710. Network 710 may comprise one or more local and/or wide area networks configured to provide users with secure, reliable, and efficient access to the server (compute) system 2720. In some embodiments, this system may be used for providing cloud-based services to external users, it may implement a private network for internal design organization users, or it may implement combinations of both private internal and third-party external compute processing services whether or not provided through cloud-based open or de-coupled restricted network interfaces.

The server system 2720 includes a plurality of servers, such as HPC (high-performance computer) and/or server pools, coupled to one another to implement a user interface front end 2725, model generation engine 2730, and a power characterization engine 2735, as shown. The servers and constituent server computer devices may be located in a single location or geographically distributed across different physical locations.

The user interface front end 2725 includes executable code to implement a user interface such as the user interface 2610 of FIG. 26. The model generation module 2730 includes executable code to implement a model generation system such as is shown in FIG. 25 to generate a hTFR based power characterization model 2530. Likewise, the power characterization engine 2735 includes executable code to implement an inference engine using one or more model(s) 2530 to characterize a power network based on a set of features drawn from an hTFR-generated data array corresponding to one or more signals sampled over a period of time for the power network.

FIG. 29 is a flow diagram showing a method for identifying anomalies in a power system in accordance with some embodiments. Initially, at 2910, sampled power signal for a device, or system, is received. For example, the signal may correspond to a voltage signal, a current signal, or both voltage and current signals, any of which including components for single or multiple phases.

At 2920, a first group of TFR values for the power signal(s) are generated using a constant bandwidth (CB) method on a first set of frequency sub-bands over a first frequency range. In some embodiments, a fundamental frequency (fₒ) may be defined, or identified, for the power signal(s). For example, in many public power distribution systems using 60 Hz power signals, a fundamental frequency (fₒ=60 Hz.) could be used. In addition, a reasonable number of harmonic-centered sub-bands, e.g., a reasonable choice for the number of CB-sub-bands may be used. In one embodiment, the number of CB-sub-bands, KCB, may be an integer number greater than 5 and less than 15.

The upper end of the CB frequency range will typically be defined by f_{min_CQ}. Any suitable CB filter structures, analog, digital, or both, such as are discussed above could be employed including those using a single-cycle-long window as the prototype low-pass filter.

At 2930, a second group of TFR values for the power signal(s) are generated using a constant quality (CQ) method on a second set of frequency sub-bands over a second frequency range. The CQ operations should employ adequate sub-band density. In some embodiments, four or more sub-bands-per-octave may be used with analytic (or at least near-analytic) filters and with non-decimated sub-band processing. Input variables for CQ processing may include: (a) the frequency range [f_{min_CQ}:f_{max_CQ}] covered by the CQ module filter bank, (b) K_{CQ}, the number of CQ sub-bands, and (c) A_{CQ}, the level of intersection between magnitude responses of adjacent sub-bands including the highest CB sub-band and lowest CQ sub-band. While the value of f_{min_CQ} typically depends primarily on K_CB (the number of sub-bands in the CB-module), the top frequency (f_{max_CQ}) can be selected based on prior knowledge about the nature of transients contained in the waveform of interest. When such information is not readily available, one can resort to a default choice f_{max_CQ}=Fₛ/2 (where Fₛ is the sampling rate used to acquire the power signal[s] being analyzed).

Once a junction edge ratio (JER) as discussed above, e.g., JER=1, value has been determined, the corresponding f_{min_CQ}-value may be selected, for example, using the relationship: f_{min_CQ}=JER(K_{CB}+1/2)f₀. So, for example, with JER=1 and KCB=8, f_{min_CQ} would be: 8.5 fo.

As with the CB filters, any suitable filter methods, digital, analog, or both, may be employed to implement the sub-band CQ processing. For example, Hamming or Morse type windows could be employed.

At 2940, the first and second groups of TFR values are processed and combined into an array of resultant TFR (or hTFR) values. At 2950, the hTFR array is then processed to identify anomalies in the acquired power signal(s) for the system under analysis. This may be done using any suitable processing approaches such as with traditional image or signal comparison techniques against known array sets for properly operating systems of the same type. Alternatively, an ML based approach may be used not only to identify any anomalies, but also, to diagnose, or assist in diagnosing, problems in the system, e.g., failed or degrading components or switching cadences.

As used in this specification, the term “embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Throughout the specification and in the claims, the term “connected” means a direct connection, such as an electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. Different circuits or modules may share or even consist of common components. For example, a controller circuit may be a circuit to perform a first function. At the same time, the same controller circuit may also be a circuit to perform another function that is related or not related to the first function.

The terms “substantially,” “close,” “approximately,” “near,” and “about,” generally refer to being within +/−10% of a target value.

Unless otherwise specified, the use of the ordinal adjectives “first,” “second,” and “third,” etc., to describe a common object, merely indicates that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As defined herein, the term “computer-readable storage medium” means a storage medium that contains or stores program code for use by or in connection with an instruction execution system, apparatus, or device. As defined herein, a “computer-readable storage medium” is not a transitory, propagating signal per se. A computer-readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer-readable storage medium. A non-exhaustive list of more specific examples of a computer-readable storage medium may include: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing.

As defined herein, the term “output” means storing in physical memory elements, e.g., devices, writing to display or other peripheral output device, sending or transmitting to another system, exporting, or the like.

As defined herein, the term “responsive to” means responding or reacting readily to an action or event. Thus, if a second action is performed “responsive to” a first action, there is a causal relationship between an occurrence of the first action and an occurrence of the second action. The term “responsive to” indicates the causal relationship.

As defined herein, the terms “one embodiment,” “an embodiment,” or similar language mean that a particular feature, structure, or characteristic described in connection with the embodiment is included in at least one embodiment described within this disclosure. Thus, appearances of the phrases “In one embodiment,” “In an embodiment,” and similar language throughout this disclosure may, but do not necessarily, all refer to the same embodiment.

As defined herein, the term “processor” means at least one hardware circuit configured to carry out instructions contained in program code. The hardware circuit may be an integrated circuit. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth.

A computer program product may include a computer-readable storage medium (or media) having computer-readable program instructions thereon for causing a processor to carry out aspects of the inventive arrangements described herein. Within this disclosure, the term “program code” is used interchangeably with the term “computer readable program instructions.” Computer-readable program instructions described herein may be downloaded to respective computing/processing devices from a computer-readable storage medium or to an external computer or external storage device via a network, for example, the Internet, a LAN, a WAN, and/or a wireless network. The network may include copper transmission cables, optical transmission fibers, wireless transmission, routers, firewalls, switches, gateway computers and/or edge devices including edge servers. A network adapter card or network interface in each computing/processing device receives computer-readable program instructions from the network and forwards the computer-readable program instructions for storage in a computer-readable storage medium within the respective computing/processing device.

Computer readable program instructions for carrying out operations for the inventive arrangements described herein may be assembler instructions, instruction-set-architecture (ISA) instructions, machine instructions, machine-dependent instructions, microcode, firmware instructions, or either source code or object code written in any combination of one or more programming languages, including an object-oriented programming language and/or procedural programming languages. Computer-readable program instructions may include state-setting data. The computer-readable program instructions may execute entirely on the user's computer, partly on the user's computer, as a stand-alone software package, partly on the user's computer, and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry, including, for example, programmable logic circuitry, an FPGA, or a PLA, may execute the computer-readable program instructions by utilizing state information of the computer-readable program instructions to personalize the electronic circuitry in order to perform aspects of the inventive arrangements described herein.

Certain aspects of the inventive arrangements are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by computer-readable program instructions, e.g., program code.

These computer-readable program instructions may be provided to a processor of a general-purpose computer, special-purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the operations specified in the flowchart and/or block diagram block or blocks.

The flowchart and block diagrams in the figures illustrate the architecture, functionality, and operation of possible implementations of systems, methods, and computer program products according to various aspects of the inventive arrangements. In this regard, each block in the flowchart or block diagrams may represent a module, segment, or portion of instructions, which comprises one or more executable instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order, while in still other examples, one or more blocks may be performed in varying order, with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and computer instructions.

What is claimed is:

1. A system, comprising:
a constant bandwidth (CB) module to generate a first group of time-frequency representation (TFR) values for a power signal acquired for a device using a first set of frequency sub-bands over a first frequency range;
a constant Q (CQ) module to generate a second group of TFR values for the power signal using a second set of frequency sub-bands over a second frequency range;
a TFR array generator coupled to both the CB and CQ modules to combine the first and second TFR values into an array of resultant TFR values; and
a power characterization module to identify an anomaly with the device based on the array of resultant TFR values.

2. The system of claim 1, wherein the first set of frequency sub-bands includes K_{CB} sub-bands, where K_{CB} is an integer value in a range that is greater than 5.

3. The system of claim 2, wherein the KCB is an integer value that is less than 15.

4. The system of claim 1, wherein the first set of frequency sub-bands consists of sub-bands having a bandwidth substantially equivalent to a fundamental frequency for the power signal.

5. The system of claim 1, wherein the CB module includes a bank of low-pass finite impulse response (FIR) filters.

6. The system of claim 5, wherein the bank of low-pass FIR filters are implemented with Hamming windows.

7. The system of claim 1, wherein the second frequency range is bounded by a lower CQ frequency value (f_{min_CQ}) and an upper CQ frequency value (f_{max_CQ}), wherein the f_{min_CQ} value corresponds to the first set of frequency sub-bands for the CB module.

8. The system of claim 1, wherein a level of intersection between magnitude responses of adjacent CQ module sub-bands is greater or equal to 1 dB.

9. The system of claim 8, wherein the level of intersection between a magnitude response of a highest CB module sub-band and a lowest CQ module sub-band is greater or equal to 1 dB.

10. The system of claim 1, wherein four or more sub-bands from the second set of frequency sub-bands are used for each octave within the second frequency range.

11. The system of claim 1, wherein the device comprises a power distribution system, and the power signals are obtained from a plurality of test access points (TAPs) within the power distribution system.

12. The system of claim 1, comprising a signal acquisition module to generate the power signal from the device, the signal acquisition module including:
a test access point (TAP) interface circuit coupled to a TAP on the device to provide an analog signal,
an analog to digital converter (ADC) coupled to the TAP interface to receive the analog signal and convert it into a digital signal, and
a signal file generator to compile the digital signal with timing information into the power signal.

13. The system of claim 1, wherein the power characterization module includes a power characterization model to identify the anomaly based on the power signal and the power characterization model.

14. The system of claim 13, comprising a model generation engine to generate the power characterization model using at least one of a convolutional neural network and recurrent neural network method.

15. A computer-readable medium having instructions that when executed by a computer system perform a method, comprising:
receiving a sampled power signal;
generating a first group of time-frequency representation (TFR) values for the received power signal;
generating a second group of TFR values for the power signal;
combining the first and second groups of TFR values into an array of resultant values; and
processing the array to identify anomalies in the received power signal.

16. The computer-readable medium of claim 15, wherein generating a first group of time frequency representation (TFR) values is performed using a constant bandwidth (CB) method on a first set of frequency sub-bands over a first frequency range.

17. The computer-readable medium of claim 16, wherein a selected number in a range between 5 and 15 harmonic-centered CB-sub-bands (KCB) are used.

18. The computer-readable medium of claim 15, wherein generating the second group of time-frequency representation values includes using a constant quality (CQ) method on a second set of frequency sub-bands over a second frequency range.

19. The computer-readable medium of claim 18, wherein four or more sub-bands-per-octave are used with analytic filters and with non-decimated sub-band processing.

20. The computer-readable medium of claim 15, wherein processing the array to identify anomalies in the received power signal is performed using a machine learning inference engine.

21. A signal acquisition apparatus, comprising:
a test access point (TAP) interface circuit to receive a power signal;
one or more filters coupled to the TAP interface circuit;
an analog to digital converter (ADC) coupled to the one or more filters;
a signal file generator coupled to the ADC to generate a digitized time-stamped version of the received power signal; and
a hybrid time-frequency representation (hTFR) engine to process the digitized time-stamped signal version to identify an anomaly in the power signal.

22. The apparatus of claim 21, wherein machine learning inference comparisons are used to identify the anomaly.

23. The apparatus of claim 21, wherein the TAP interface circuit includes a high voltage probe.

24. The apparatus of claim 21, wherein the hTFR engine comprises:
a constant bandwidth (CB) module to generate a first group of TFR values using a first set of frequency sub-bands over a first frequency range;
a constant Q (CQ) module to generate a second group of TFR values for the power signal using a second set of frequency sub-bands over a second frequency range;
a time-frequency representation (TFR) array generator coupled to both the CB and CQ modules to combine the first and second groups of TFR values into an array of resultant TFR values; and
a power characterization module to identify an anomaly based on the array of resultant TFR values.

25. The apparatus of claim 24, wherein the first set of frequency sub-bands includes KCB sub-bands, where KCB is an integer value in a range that is greater than 5.
